(19) United States
(12) Patent Application Publication
(10) Pub. No.: US 2009/0229872 A1
(43) Pub. Date: Sep. 17, 2009

(54) ELECTRONIC COMPONENT BUILT-IN BOARD, MANUFACTURING METHOD OF ELECTRONIC COMPONENT BUILT-IN BOARD, AND SEMICONDUCTOR DEVICE

(75) Inventor: Eiji TAKAIKE, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/401,721

(22) Filed: Mar. 11, 2009

(30) Foreign Application Priority Data
Mar. 17, 2008 (JP) NO. 2008-068532

(51) Int. Cl. H05K 1/11; H05K 1/00; H05K 3/00

(52) U.S. Cl. 174/261; 174/250; 29/829

(57) ABSTRACT

An electronic component built-in board including an electronic component having an electrode; a conductive material part arranged in an identical plane to the electronic component; and a resin member configured to support the electronic component and the conductive material part in a state where an upper side and a bottom side of the electronic component and an upper side and a bottom side of the conductive material part are exposed.

### BACKGROUND OF THE INVENTION

1. Field of the Invention

The present invention generally relates to an electronic component built-in board, an electronic component built-in board manufacturing method and a semiconductor device.

More specifically, the present invention relates to an electronic component built-in board including built-in electronic components and a manufacturing method of the electronic component built-in board, and a semiconductor device.

2. Description of the Related Art

Recently, miniaturization of semiconductor chips (such as semiconductor chips for a central processing unit (CPU)) has been advanced and the number of multi-terminals of the semiconductor chips has been increased. There is provided a semiconductor device that includes a wiring board for mounting the semiconductor chips, and another wiring board (an electronic component built-in board 303 shown in FIG. 1) including built-in electronic components and connected to a mounting board such as a mother board, in which the wiring boards are separately included in a stacked manner.

FIG. 1 is a cross section of a related art semiconductor device.

Referring to FIG. 1, a related art semiconductor device 300 includes a wiring board 301, a semiconductor chip 302 and an electronic component built-in board 303.

The wiring board 301 is arranged between the semiconductor chip 302 and the electronic component built-in board 303. The wiring board 301 includes a multilayer insulating part 311 formed by laminating plural insulation layers, chip connection pads 312 provided on a front surface 311A of the multilayer insulating part 311 for chip connection, board connection pads 313 provided on a rear surface 311B of the multilayer insulating part 311, and wiring patterns 314 formed in the multilayer insulating part 311 for electrically connecting between the board connection pads 313 and the chip connection pads 312.

The wiring board 301 is electrically connected to the semiconductor chip 302 and the electronic component built-in board 303. The wiring board 301 is a board for adjusting the wiring pitch of the board connection pads 313 so that the board connection pads 313 face pads 329 forming the electronic component built-in board 303 and pad parts 343.

The semiconductor chip 302 includes electrode pads 316. The electrode pads 316 are electrically connected to the chip connection pads 312 via bumps 305. For example, a semiconductor chip of a CPU may be used for the semiconductor chip 302.

The electronic component built-in board 303 is arranged below the wiring board 301. The electronic component built-in board 303 includes insulation layers 318, 320, and 327, electronic components (or referred to as electronic components) 319, connection pads 321 for connecting electronic components, wiring patterns 322,328, pads 324, 329, external connection terminals 325, 333, and penetrating electrodes 331.

The insulating layer 318 includes through-holes 335. Electronic components 319 are accommodated in the through-holes 335. The electronic components 319 include electrodes 337. The electrodes 337 are electrically connected to the connection pads 321 with solder 338.

The insulating layer 320 is provided on the rear surface 318B of the insulating layer 318. The connection pads 321 are formed on the surface of the insulating layers 320 exposed by the through-holes 335. The wiring patterns 322 are formed on the insulating layer 320. The wiring patterns 322 penetrate the insulating layer 320. Parts of the wiring patterns 322 penetrating the insulating layer 320 are connected to the connection pads 321. The wiring pattern 322 includes pad parts 341 on which the external connection terminals 325 are formed.

Pads 324 are arranged on the rear surface of the insulating layer 320. The external connection terminals 325 are formed on the pads 324. The insulating layer 327 is formed on the surface 318A of the insulating layer 318.

The wiring patterns 328 are formed in the insulating layer 327. The wiring patterns 328 penetrate the insulating layer 327. Parts of the wiring patterns 328 penetrating the insulating layer 327 are connected to the electrode 337. The wiring patterns 328 include the pads 343 on which the external connection terminals 333 are formed. The pads 343 are electrically connected to the board connection pads 313 via the external connection terminals 333.

Pads 329 are formed on the surface of the insulating layer 327. The pads 329 are electrically connected to the pads 324 via the penetrating electrodes 331. Also, the pads 329 are electrically connected to the board connection pads 313 via the external connection terminals 333.

The penetrating electrodes 331 are formed to penetrate the insulating layers 318, 320 and 327. The upper sides of the penetrating electrodes 331 are connected with the pads 329. It is described in Japanese Patent Application Publication No. 2005-217382 that the bottom sides of the penetrating electrodes 331 are connected to the pads 324.

In the related art electronic component built-in board 303, the electrical connection reliability between the pads 321 and the electrodes 337 of the electronic components 319 and between the wiring patterns 328 and the electrodes 337 of the electronic components 319 may be degraded by a difference of a thermal expansion coefficient between the electronic components 319 and the insulating layers 318, 320, and 327.

Further, there is a problem that the related art electronic component built-in board 303 cannot be downsized in the thickness direction, since the related art electronic component built-in board 303 includes the insulating layers 320 and 327, and the wiring patterns 322 and 328 on the top and bottom of the electronic components 319.

Also, the related art semiconductor device 300 including the electronic component built-in board 303 described above has problems, in which the electrical connection reliability of the semiconductor device 300 may be degraded, and the semiconductor device 300 cannot be downsized in the thickness direction of the semiconductor device.

### SUMMARY OF THE INVENTION

Accordingly, embodiments of the present invention may provide a novel and useful electronic component built-in board solving one or more of the problems discussed above.

It is a general object of the present invention to provide an electronic component built in board, a manufacturing method, and a semiconductor device which can improve the electrical connection reliability and downsize the electronic component built-in board in the thickness direction, in which the problem above is minimized.

More specifically, the embodiments of the present invention may provide an electronic component built-in board including an electronic component having an electrode; a conductive material part arranged in an identical plane to the electronic component; and a resin member configured to support the electronic component and the conductive material part in a state where an upper side and a bottom side of the electronic component and an upper side and a bottom side of the conductive material part are exposed.

One aspect of the present invention may be to provide a manufacturing method for manufacturing an electronic component built-in board configured to include an electronic component having and electrode, a conductive material part arranged in an identical plane to the electronic component, and a resin member, the manufacturing method comprising the steps of: providing the electronic component and the conductive material part on a support member; forming the resin member so as to cover at least a side of the electronic component and a side of the conductive material part; exposing an upper side of the electrode and an upper side of the conductive material part from the resin member; and removing the support member after the step of exposing.

Other objects, features, and advantages of the present invention will become more apparent from the following detailed description when read in conjunction with the accompanying drawings.

### BRIEF DESCRIPTION OF THE DRAWINGS

FIG. 1 is a cross section of a related art semiconductor device;

FIG. 2 is a cross section of a semiconductor device according to the first embodiment of this invention;

FIG. 3 is a cross section of the semiconductor device according to the first modified example of the first embodiment of this invention;

FIG. 4 is a cross section of the semiconductor device according to the second modified example of the first embodiment of this invention;

FIG. 5 is a drawing showing a manufacturing process of an electronic component built-in board according to the first embodiment of this invention (case 1);

FIG. 6 is a drawing showing a manufacturing process of the electronic component built-in board according to the first embodiment of this invention (case 2);

FIG. 7 is a drawing showing a manufacturing process of the electronic component built-in board according to the first embodiment of this invention (case 3);

FIG. 8 is a drawing showing a manufacturing process of the electronic component built-in board according to the first embodiment of this invention (case 4);

FIG. 9 is a drawing showing a manufacturing process of the electronic component built-in board according to the first embodiment of this invention (case 5);

FIG. 10 is a drawing showing a manufacturing process of the electronic component built-in board according to the first embodiment of this invention (case 6);

FIG. 11 is a drawing showing a manufacturing process of the electronic component built-in board according to the first embodiment of this invention (case 7);

FIG. 12 is a drawing showing a manufacturing process of the electronic component built-in board according to the second modified example of the first embodiment of this invention (case 1);

FIG. 13 is a drawing showing a manufacturing process of the electronic component built-in board according to the second modified example of the first embodiment of this invention (case 2);

FIG. 14 is a drawing showing a manufacturing process of the electronic component built-in board according to the second modified example of the first embodiment of this invention (case 3);

FIG. 15 is a drawing showing a manufacturing process of the electronic component built-in board according to the second modified example of the first embodiment of this invention (case 4);

FIG. 16 is a cross section of the semiconductor device according to the second embodiment of this invention;

FIG. 17 is a cross section of a structure part used when the electronic component built-in board according to the second embodiment of this invention is manufactured;

FIG. 18 is a cross section of the semiconductor device according to a modified example of the second embodiment of this invention;

FIG. 19 is a cross section of the semiconductor device according to the third embodiment of this invention;

FIG. 20 is a drawing showing a manufacturing process of the semiconductor device according to the third embodiment of this invention (case 1);

FIG. 21 is a drawing showing a manufacturing process of the semiconductor device according to the third embodiment of this invention (case 2);

FIG. 22 is a drawing showing a manufacturing process of the semiconductor device according to the third embodiment of this invention (case 3);

FIG. 23 is a drawing showing a manufacturing process of the semiconductor device according to the third embodiment of this invention (case 4);

FIG. 24 is a drawing showing a manufacturing process of the semiconductor device according to the third embodiment of this invention (case 5);

FIG. 25 is a drawing showing a manufacturing process of the semiconductor device according to the third embodiment of this invention (case 6);

FIG. 26 is a drawing showing a manufacturing process of the semiconductor device according to the third embodiment of this invention (case 7);

FIG. 27 is a drawing showing a manufacturing process of the semiconductor device according to the third embodiment of this invention (case 8);

FIG. 28 is a cross section of the semiconductor device according to the fourth embodiment of this invention;

FIG. 29 is a cross section of the electronic component built-in board according to a modified example of the fourth embodiment of this invention;

FIG. 30 is a drawing showing a manufacturing process of the electronic component built-in board according to the fourth embodiment of this invention (case 1);

FIG. 31 is a drawing showing a manufacturing process of the electronic component built-in board according to the fourth embodiment of this invention (case 2);

FIG. 32 is a cross section of the semiconductor device according to the fifth embodiment of this invention; and

FIG. 33 is a cross section of the electronic component built-in board according to a modified example of the fifth embodiment of this invention.

### DETAILED DESCRIPTION OF THE PREFERRED EMBODIMENTS

In the following, preferred embodiments of the present invention will be described with accompanying drawings.

### First Embodiment

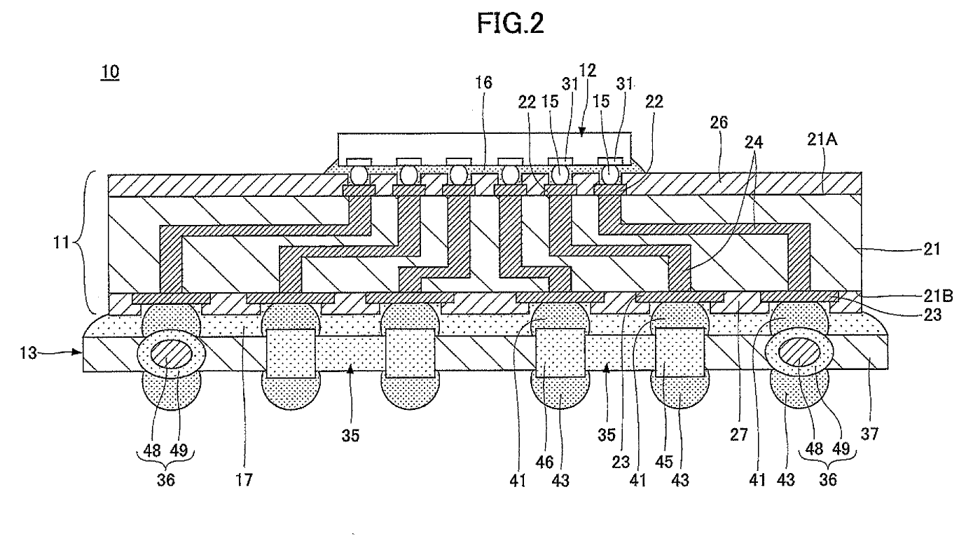

FIG. 2 is a cross section of a semiconductor device according to the first embodiment of this invention.

As shown in FIG. 2, a semiconductor device 10 according to the present embodiment includes a wiring board 11, a semiconductor chip 12, an electronic component built-in board 13 and underfill resin 17.

The wiring board 11 is arranged between the semiconductor chip 12 and the electronic component built-in board 13. The wiring board 11 includes a multilayer insulating part 21, chip connection pads 22, board connection pads 23, wiring patterns 24, and solder resist layers 26 and 27. The multilayer insulating part 21 is formed from stacked plural insulating layers. As the insulating layer forming the multilayer insulating part 21, for example, a resin layer can be used (specifically, the resin layer may be epoxy resin or polyimide resin).

The chip connection pads 22 are formed on the front surface 21A of the multilayer insulating part 21 in a region (the main surface of the wiring board 11) corresponding to a mounting region of the semiconductor chip 12. For example, copper (Cu) can be used as a material of the chip connection.

The board connection pads 23 are formed on the rear (or bottom) surface 21B (opposite side of the main surface of the wiring board 11) of the multilayer insulating part 21. The board connection pads 23 are arranged to face upper sides of electrodes 45 and 46 of electronic components 35 to be described later or upper sides of conductive material parts 36. The board connection pads 23 are electrically connected to the chip connection pads 22 via the wiring patterns 24. The board connection pads 23 are connected to external connection terminals 41 to be described later provided on the electronic component built-in board 13.

The wiring patterns 24 are formed in the multilayer insulating part 21. One of sides of the wiring patterns 24 are connected to the chip connection pads 22, and the other sides of the wiring patterns 24 are connected to the board connection pads 23.

The solder resist layers 26 are formed on the front surface 21A of the multilayer insulating part 21. The solder resist layer 26 includes opening parts which expose the front surfaces of the chip connection pads 22.

The solder resist layer 27 is formed on the rear surface 21B of the multilayer insulating part 21. The solder resist layer 27 includes opening parts which expose the rear surfaces of the board connection pads 23.

The wiring board 11 described above is a board for adjusting the wiring pitch of the board connection pads 23 so that the board connection pads 23 face the upper sides of the electrodes 45 and 46 to be described later formed in the electronic component built-in board 13 or the upper sides of the conductive material parts 36.

The semiconductor chip 12 is disposed on the wiring board 11. The semiconductor chip 12 includes electrode pads 31. The electrode pads 31 are electrically connected to the chip connection pads 22 via the bumps 15. In other words, the semiconductor chip 12 is connected to the chip connection pads 22 by flip chip connection. Further, the underfill resin 16 is filled between the semiconductor chip 12 and the wiring board 11. With increasing demand for miniaturization, the number of terminals of a semiconductor chip has been increased. The semiconductor chip 12 is such semiconductor chip. For example, a CPU chip can be used for the semiconductor chip 12.

The electronic component built-in board 13 is arranged below the wiring board 11. The electronic component built-in board 13 includes the electronic components 35, the conductive material parts 36, a resin member 37 and the external connection terminals 41 and 43.

The electronic components 35 include a pair of the electrodes 45 and 46. The electrodes 45 are the electrodes used for power supply, and the electrodes 46 are the electrodes used for the ground. The upper sides and bottom sides of the electrodes 45 and 46 are exposed from the resin member 37. The external connection terminals 41 are provided on the upper sides of the electrodes 45 and 46. The electrodes 45 and 46 are electrically connected to the wiring board 11 via the external connection terminals 41. The bottom sides of the electrodes 45 and 46 are provided with the external connection terminals 43. The sides of the electronic components 35 are supported by the resin member 37. For example, a passive device is used for the electronic components 35.

For example, a chip capacitor, a chip resistor, or a chip inductor is used as the passive device.

The conductive material parts 36 are arranged in an identical plane to the electronic components 35. The conductive material parts 36 are metal core balls, which include metal balls 48 and solder 49 covering the metal ball 48 (e.g. Cu balls). The upper sides and bottom sides of the conductive material parts 36 are exposed from the resin member 37. The conductive material parts 36 are signal terminals which provide signals to the semiconductor chip 12.

The resin member 37 is a member having a plate-shaped configuration. The resin member 37 supports the electronic components 35 and the conductive material parts 36 by contacting the side of the electronic components 35 and the side of the conductive material parts 36. The resin member 37 exposes the upper sides and bottom sides of the electronic components 35, and also exposes the upper sides and bottom sides of the conductive material parts 36.

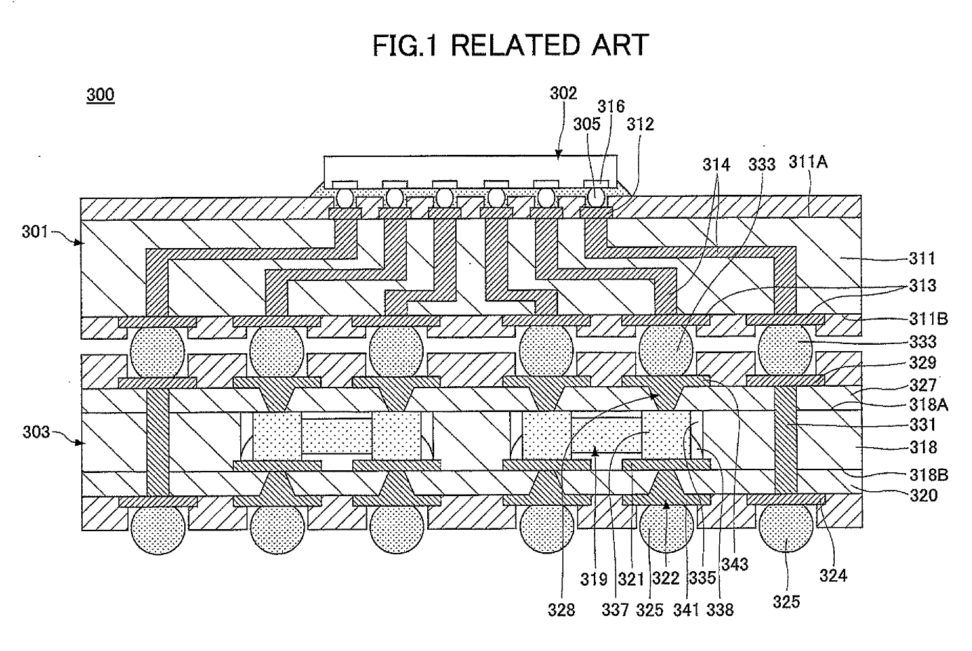

In this way, the resin member 37 supporting the electronic components 35 and the conductive material parts 36 is formed to expose the upper sides and bottom sides of the electrodes 45 and 46 of the electronic components 35 and the bottom sides and the upper sides of the conductive material parts 36. With this, compared to the related art electronic component built-in board 303 (see FIG. 1) which includes parts such as the insulating layers 320 and 327 and the wiring patterns 322 and 328 electrically connected to the electronic components 35 at the upper side and bottom side of the electronic components 319, the electrical connection reliability of the electronic component built-in board 13 can be improved, and the electronic component built-in board 13 can be downsized in the thickness direction.

Further, the improvement of the electrical connection reliability of the electronic component built-in board 13 can improve the electrical connection reliability of the semiconductor device 10 including the electronic component built-in board 13. The downsizing of the electronic component built-in board 13 in the thickness direction can also downsize the semiconductor device 10 in the thickness direction.

For example, a material such as epoxy resin or mold resin can be used for the material of the resin member 37. Generally, since a content of the silicone filler in the mold resin (or, filler of aluminum) is high (e.g. 70 wt % through 80 wt %), the difference of the thermal expansion coefficient between the electronic components 35 and the resin member 37 can be decreased when the mold resin is used as the material of the resin member 37.

Also, it is preferable that the thickness of the resin member 37 is smaller than the height of the electronic components 35 and the conductive material parts 36. Specifically, when the height of the electronic components 35 is 0.5 μm and the height of the conductive material parts 36 is 0.35 μm, for example, the thickness of the resin member 37 may be 0.3 μm.

In this way, by making the thickness of the resin member 37 to be smaller than the height of the electronic components 35 and the conductive material parts 36, the electronic component built-in board 13 can be further downsized in the thickness direction.

The external connection terminals 41 are provided between the upper sides of the electrodes 45 and 46 of the electronic components 35 and the board connection pads 23 formed on the wiring board 11, and also between the upper sides of the conductive material parts 36 and the board connection pads 23. The external connection terminals 41 electrically connect between the electronic components 35 and the board connection pads 23, and electrically connect between the conductive material parts 36 and the board connection pads 23. For example, solder such as Sn—Ag—Cu solder may be used as the external connection terminals 41.

In FIG. 2, although an example is given for use of the solder as the external connection terminals 41, external connection terminals (not shown) may be used instead of the external connection terminals 41, in which the external connection terminals are arranged inside of the solder shown in FIG. 2 and include Au bumps which contact the upper sides of the electrodes 45 and 46 or the upper sides of the conductive material parts 36 (not shown) and include solder covering the Au bumps.

In this way, by forming the external connection terminals which are arranged inside of the solder and include Au bumps and the solder covering the Au bumps, the connection strength can be improved between the board connection pads 23 and the electrodes 45 and 46 and between the board connection pads 23 and the conductive material parts 36.

The external connection terminals 43 are formed on the bottom sides of the electrodes 45 and 46 of the electronic components 35 and the bottom sides of the conductive material parts 36. The external connection terminals 43 are terminals which electrically connect between the electronic component built-in board 13 and the mounting board (not shown) such as a mother board.

For example, solder such as Sn—Ag—Cu solder can be used for the external connection terminals 43.

In FIG. 2, although an example is given for use of the solder as the external connection terminals 43, external connection terminals (not shown) may be used instead of the external connection terminals 43, in which the external connection terminals are arranged inside of the solder shown in FIG. 2 and include Au bumps which contact the upper sides of the electrodes 45 and 46 or the upper sides of the conductive material parts 36 (not shown) and include solder covering the Au bumps.

In this way, by forming the external connection terminals which are arranged inside of the solder and include Au bumps and the solder covering the Au bumps, the connection strength can be improved between the connection pads formed on the mounting board and the electrodes 45 and 46 and between the connection pads formed on the mounting board and the conductive material parts 36, when the electronic component built-in board 13 is mounted on the mounting board (not shown).

The underfill resin 17 is formed to fill a gap between the wiring board 11 and the electronic component built-in board 13. The underfill resin 17 is resin which improves the connection strength between the wiring board 11 and the electronic component built-in board 13.

According to the electronic component built-in board of this embodiment, the resin member 37 having a plate-shaped configuration supports the electronic components 35 and the conductive material parts 36 by exposing the upper sides of and bottom sides of the electrodes 45 and 46 of the electronic components 35 and the bottom side and the upper sides of the conductive material parts 36. With this, compared to the related art electronic component built-in board 300 (see FIG. 1) which includes parts such as the insulating layers 320 and 327 and the wiring patterns 322 and 328 electrically connected to the electronic components 35 at the upper side and bottom side of the electronic components 319, the electrical connection reliability of the electronic component built-in board 13 can be improved, and the electronic component built-in board 13 can be downsized in the thickness direction.

According to the semiconductor device of the present embodiment, there is provided the electronic component built-in board 13 which is downsized in the thickness direction and improved in the electrical connection reliability, and thus the semiconductor device 10 can be improved in the electrical connection reliability and downsized in the thickness direction of the semiconductor device 10.

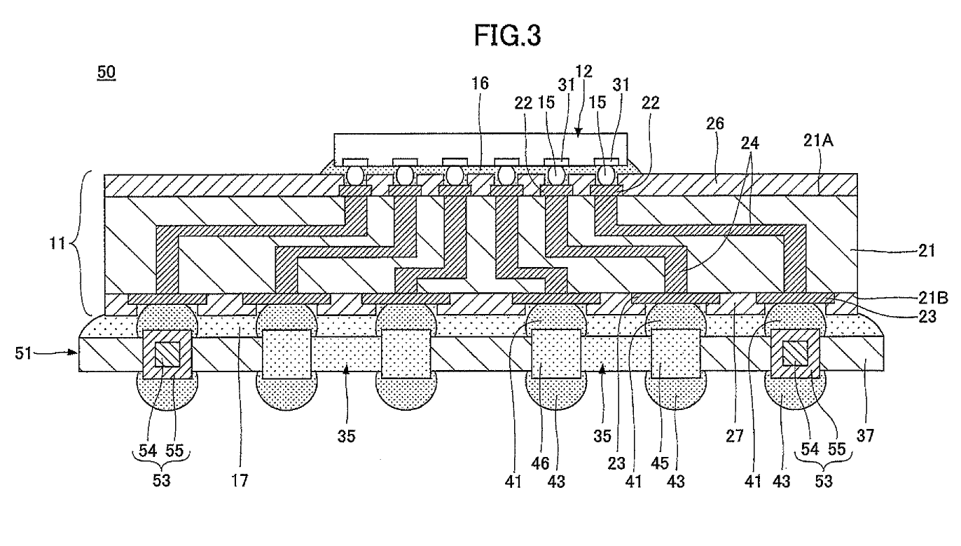

FIG. 3 is a cross section of a semiconductor device related to the first modification example of the first embodiment of this invention. In FIG. 3, the identical symbols are used for the component parts which are identical to those of the semiconductor device 10 of the first embodiment shown in FIG. 2.

Referring to FIG. 3, a semiconductor device 50 of the first modified example of the first embodiment includes a configuration similar to that of the semiconductor device 10 except that an electronic component built-in board 51 is used instead of the electronic component built-in board 13 (FIG. 2) which is used in the semiconductor device 10 of the first embodiment.

The electronic component built-in board 51 has the similar configuration to that of the electronic component built-in board 13 except that conductive material parts 53 are provided instead of the conductive material parts 36 formed in the electronic component built-in board 13.

The conductive material parts 53 are signal terminals which supply signals to the semiconductor chip 12. The conductive material parts 53 are formed to be pillar shaped. The conductive material parts 53 include pillar shaped members 54 having conductivity and metal films 55 covering the pillar shaped members 54. For example, an alloy including such as Ni—Co alloys may be used as the material of the pillar shaped members 54. For example, an Au film may be used for the metal film 55.

In this way, by use of the conductive material parts 53 which include the pillar shaped members 54 having conductivity and the metal films 55 covering the pillar shaped members 54 as the signal terminals, the height of the conductive material parts 53 can be increased to be higher than the conductive material parts 36 (specifically, a metal core ball) described above. With this, the height of the conductive material parts 53 can be adjusted according to the height of the electronic components 35.

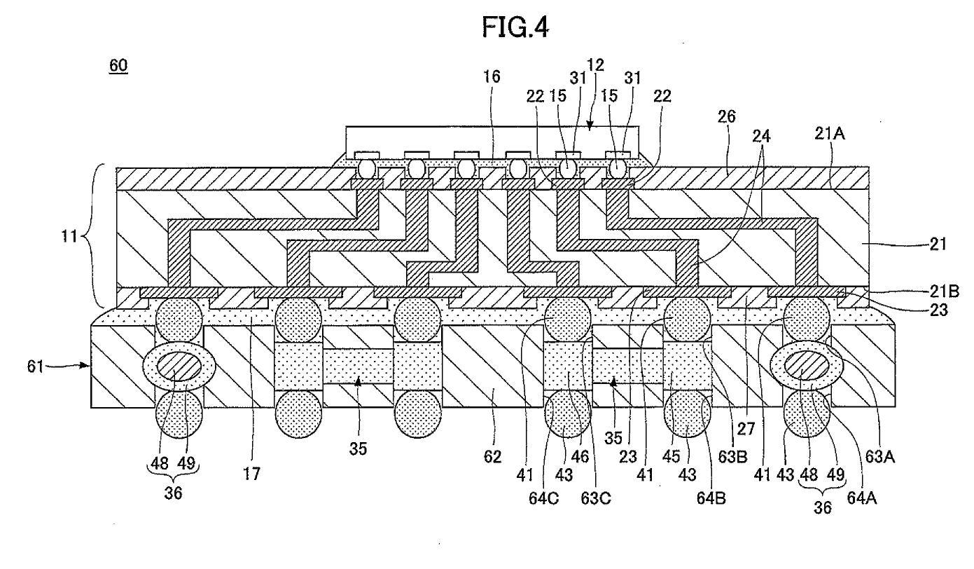

FIG. 4 is a cross section of the semiconductor device according to the second modified example of the first embodiment of this invention. In FIG. 4, the identical symbols are used for the component parts which are identical to those of the semiconductor device 10 of the first embodiment.

Referring to FIG. 4, a semiconductor device 60 of the second modified example of the first embodiment includes a configuration similar to that of the semiconductor device 10 except that an electronic component built-in board 61 is used instead of the electronic component built-in board 13 (FIG. 2) which is used in the semiconductor device 10 of the first embodiment.

The electronic component built-in board 61 has a similar configuration to that of the electronic component built-in board 13 except that the resin member 62 is provided instead of the resin member 37 provided in the electronic component built-in board 13.

The resin member 62 is formed to cover the side of the electronic components 35, the upper side and bottom side of the electronic components 35 without covering parts of the electrodes 45 and 46, and the side of the conductive material parts 36. The thickness of the resin member 62 is designed to be thicker than the thickness of the resin member 37. Specifically, when the height of the electronic components 35 is 0.5 μm and the height of the conductive material parts 36 is 0.35 μm, for example, the thickness of the resin member 62 may be 0.7 μm.

The resin member 62 includes opening parts 63A, 63B and 63C which accommodate part of the external connection terminals 41, and 64A, 64B and 64C which accommodate part of the external connection terminals 43. The opening part 63A is formed to expose the upper sides of the conductive material parts 36. The opening part 63B is formed to expose the upper side of the electrode 45. The opening part 63C is formed to expose the upper side of the electrode 46. The opening part 64A is formed to expose the bottom sides of the conductive material part 36. The opening part 64B is formed to expose the bottom side of the electrode 45. The opening part 64C is formed to expose the bottom side of the electrode 46.

In this way, by forming the opening parts 63A, 63B and 63C which accommodate the part of the external connection terminals 41 in the resin member 62 being thicker than the resin member 37, the parts constituting the opening parts 63A, 63B, and 63C of the resin member 62 regulate positions of the external connection terminals 41, so that the adjacent external connection terminals 41 can be prevented from short circuiting.

Also, by forming the opening parts 64A, 64B and 64C which accommodate the part of the external connection terminals 43 in the resin member 62 being thicker than the resin member 37, the parts constituting the opening parts 64A, 64B, and 64C of the resin member 62 regulate positions of the external connection terminals 43, so that the adjacent external connection terminals 43 can be prevented from short circuiting.

Further, instead of the resin member 35 provided in the electronic component built-in board 51 (FIG. 3) described above, the resin member 62 shown in FIG. 4 may be provided as the resin member of the electronic component built-in board 51.

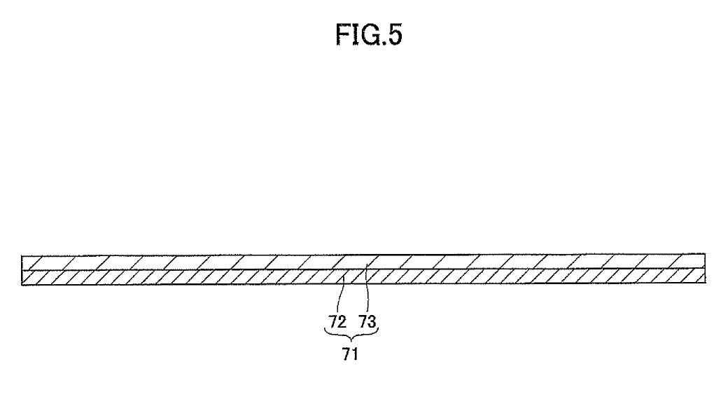

FIG. 5 through FIG. 11 are drawings showing a manufacturing process of the electronic component built-in board according to the first embodiment of the present invention. In FIG. 5 through FIG. 11, the identical symbols are used for the component parts which are identical to those of the electronic component built-in board 13 of the first embodiment.

Referring to FIG. 5 through FIG. 11, a description will be given for the manufacturing method of the electronic component built-in board 13 of the first embodiment. In a process shown in FIG. 5, there is provided a support member 71 which includes a main supporting part 72 and an adhesion layer 73 stacked on the main supporting part 72. For example, as the main supporting part 72, a metal foil such as a Cu foil or a metal layer such as Cu layer can be used. When the Cu foil is used as the main supporting part 72, the thickness of the main supporting part 72 may be 0.8 μm. The adhesion layer 73 is used for temporarily fixing the electronic components 35 and the conductive material parts 36. For example, as the adhesion layer 73, a resin layer with a semi-cured state such as an epoxy resin layer may be used. When the resin layer of a semi-cured state is used as the adhesion layer 73, for example, the thickness of the adhesion layer 73 may be approximately 20 μm.

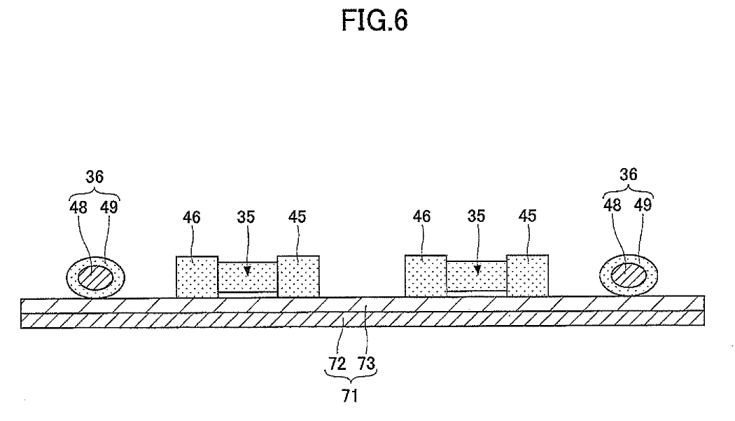

Next, in the process shown in FIG. 6, the electronic components 35 and the conductive material parts 36 are disposed on the adhesion layer 73 (referred to as the arrangement process of electronic components and conductive material parts). With this, the electronic components 35 and the conductive material parts 36 are arranged on the identical plane and temporarily fixed on the adhesion layer 73.

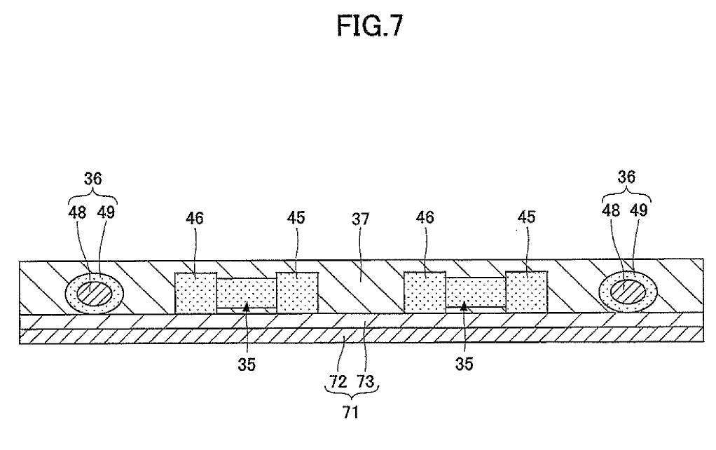

In the process shown in FIG. 7, on the front surface of the adhesion layer 73, the resin member 37 is formed to cover at least the sides of the electronic components 35 and the sides of the conductive material parts 36 (referred to as the resin member formation process). Specifically, a resin tablet (not shown) is mounted on the obtained structure shown in FIG. 6, and subsequently the resin tablet is pressed by a flat metal plate so that the resin member 37 is formed. At this stage, the upper sides of the electronic components 35 and the upper sides of the conductive material parts 36 are covered with the resin member 37, and the thickness of the resin member 37 of FIG. 7 is thicker than that of the resin member 37 of FIG. 2. In this embodiment, a description will be given in the following for a case where the resin member 37 is formed to cover the upper sides of the electronic components 35 and the upper sides of the conductive material parts 36 as an example. Further, in the resin member formation process, the resin member 37 may be formed to expose the upper sides of the electronic components 35 and the upper sides of the conductive material parts 36.

For example, epoxy resin or mold resin may be used as the material of the resin tablet. When the mold resin (a content of silicone filler or, filler of aluminum is high, for example, 70 wt % through 80 wt %) is used as the material of the resin member 37, the difference of the thermal expansion coefficient between the electronic components 35 and the resin member 37 can be decreased.

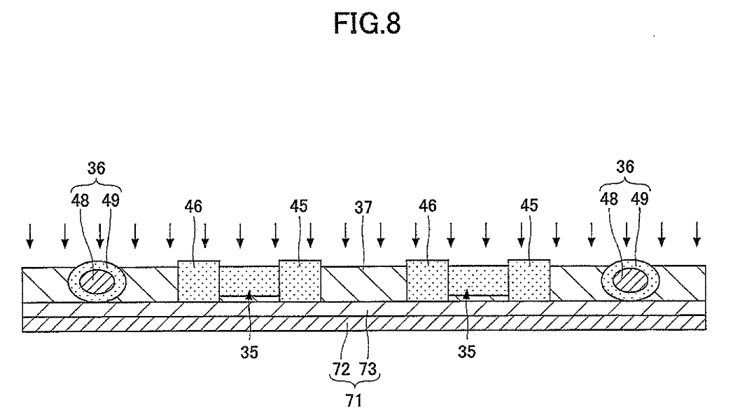

Next, in the process shown in FIG. 8, by removing the whole upper part of the resin member 37 as shown in FIG. 7, the upper side of the electrodes 45 and 46 and the upper side of the conductive material parts 36 are exposed from the resin member 37 (referred to as the resin member removal process). Specifically, by performing an ashing process of the resin member 37 from the front surface of the resin member 37 shown in FIG. 7, the resin member 37 is removed until the upper side of the electrodes 45 and 46 and the upper sides of the conductive material parts 36 are exposed. The ashing process above may be performed, for example, by use of oxygen (O₂) gas having a purity of 99.99% (the oxygen gas may be mixed with argon (Ar) gas and carbon fluoride gas such as CF₄), with a gas flow rate of 500 sccm at a radio frequency (RF) power of approximately 350 W at a frequency of 13.56 MHz under a pressure of approximately 133 Pa at a temperature ranging from approximately 90° C. to 120° C. in the process chamber. In this case, the process time may be approximately 15 min.

In this way, by removing the resin member 37 with the ashing process, the upper side of the electrodes 45 and 46 and the upper side of the conductive material parts 36 can be exposed from the resin member 37 without causing any damage to the electronic components 35 and the conductive material parts 36.

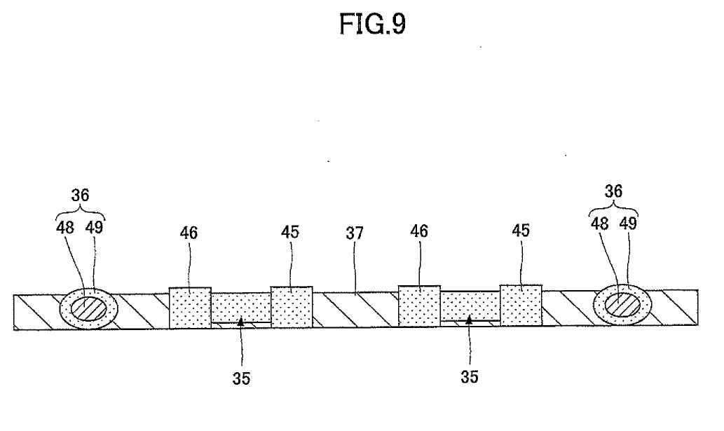

Next, in the process shown in FIG. 9, the support member 71 of FIG. 8 is removed (referred to as the support member removal process).

Specifically, for example, the support member 71 is peeled from the resin member 37.

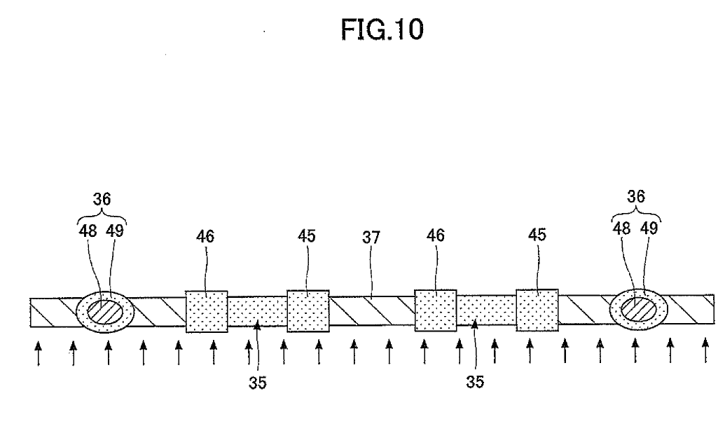

In the process shown in FIG. 10, by removing the whole lower part of the resin member 37 of FIG. 9, the bottom sides of the electrodes 45 and 46 and the bottom sides of the conductive material parts 36 are certainly exposed from the resin member 37. Specifically, by performing the ashing process for the resin member 37 from the rear surface of the resin member 37 of FIG. 9, the whole lower part of the resin member 37 is removed. The ashing process above may be performed, for example, by use of oxygen (O₂) gas having a purity of 99.99% (the oxygen gas may be mixed with argon (Ar) gas and carbon fluoride gas such as CF₄), with a gas flow rate of 500 sccm at a radio frequency (RF) power of approximately 350 W at a frequency of 13.56 MHz under a pressure of approximately 133 Pa at a temperature ranging from approximately 90° C. to 120° C. in the process chamber. In this case, the process time may be approximately 15 min.

In this way, by removing the whole lower part of the resin member 37 with the ashing process, the lower sides of the electrodes 45 and 46 and the lower sides of the conductive material parts 36 can be certainly exposed from the resin member 37 without causing any damage to the electronic components 35 and the conductive material parts 36.

Further, if the bottom sides of the electrodes 45 and 46 and the bottom sides of the conductive material parts 36 formed in the obtained structure of FIG. 9 are sufficiently exposed from the resin member 37, the process shown in FIG. 10 is not necessary.

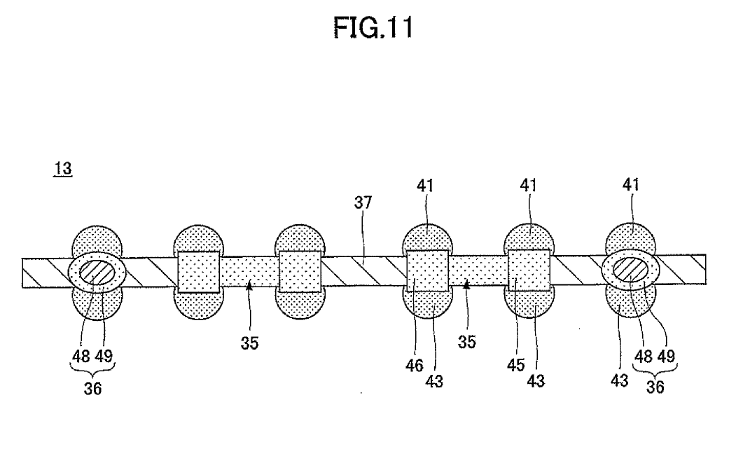

Next, in the process shown in FIG. 11, the external connection terminals 41 are formed on the upper side of the electrodes 45 and 46 and the upper side of the conductive material parts 36, and the external connection terminals 43 are formed on the bottom sides of the electrodes 45 and 46 and the bottom sides of the conductive material parts 36. With this, the electronic component built-in board 13 is manufactured. As the external connection terminals 41 and 43, for example, solder such as Sn—Ag—Cu solder may be used. In FIG. 11, although an example is given for use of the solder as the external connection terminals 41 and 43, by forming Au bumps (not shown) contacting the electrodes 45 and 46 or the conductive material parts 36 for the solder shown in FIG. 11, external connection terminals including Au bumps and solder covering the Au bumps may be formed.

According to the manufacturing method of the electronic component built-in board of this embodiment, the electronic components 35 including the electrodes 45 and 46 and the conductive material parts 36 are arranged in an identical plane to the support member 71. Also the resin member 37 is formed to cover at least the side of the electronic components 35 and the side of the conductive material parts 36. Subsequently, the upper side of the electrodes 45 and 46 and the upper side of the conductive material parts 36 are exposed from the resin member 37. The support member 71 is removed, and the external connection terminals 41 are formed on the upper side of the electrodes 45 and 46 and the upper side of the conductive material parts 36, and the external connection terminals 43 are formed on the bottom sides of the electrodes 45 and 46 and the bottom sides of the conductive material parts 36. Thus, the electrical connection reliability of the electronic component built-in board 13 can be improved, and further the electronic component built-in board 13 can be downsized in the thickness direction.

Further, the electronic component built-in board 51 of the first modified example of the first embodiment may be manufactured by a method similar to the manufacturing method of the electronic component built-in board 13 described above.

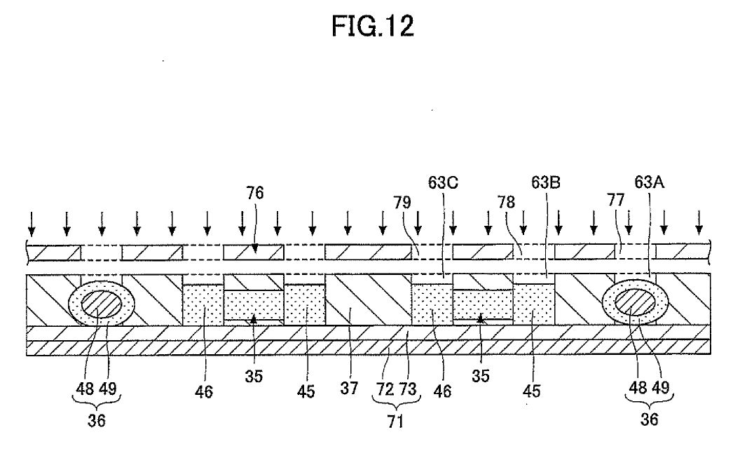

FIG. 12 through FIG. 15 are drawings showing a manufacturing process of the electronic component built-in board according to the second modified example of the first embodiment of the present invention. In FIG. 12 through FIG. 15, the identical symbols are used for the component parts which are identical to those of the electronic component built-in board 61 of the second modified example of the first embodiment.

Referring to FIG. 12 through FIG. 15, a description will be given for the manufacturing method of the electronic component built-in board 61 of the second modified example of the first embodiment. The structure shown in FIG. 7 is formed first by performing a process similar to that described in the FIG. 5 through FIG. 7.

In the process shown in FIG. 12, a mask 76 having through-holes 77-79 are arranged on the upper side of the structure part shown in FIG. 11, and the parts of the resin member 37 facing the through-holes 77-79 are removed by the ashing process with the mask 76, so that the opening parts 63A, 63B and 63C are formed in the resin member 37 (referred to as the resin member removal process).

The through-holes 77 are formed in the parts of the mask 76 facing the upper side of the conductive material parts 36, and the through-holes 78 are formed in the parts of the mask 76 facing the upper side of the electrodes 45.
Further, the through-holes 79 are formed in the parts of the mask 76 facing the upper side of the electrodes 46.

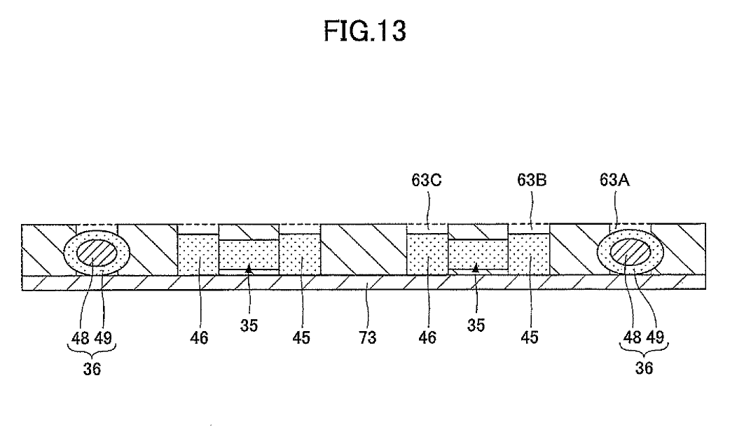

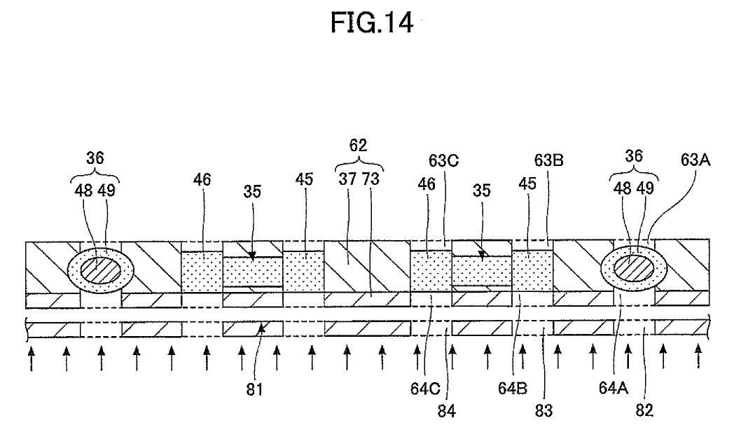

Next, in the process of FIG. 13, the main supporting part 72 formed on a structure part shown in FIG. 12 is removed. Specifically, when the main supporting part 72 is a Cu foil, the main supporting part 72 is removed by an etching process. In a process shown in FIG. 14, the mask 81 having the through-holes 82-84 is arranged below the structure of FIG. 13, the parts of the resin member 37 facing the through-holes 82-84 are removed by the ashing process with the mask 81, so that the opening parts 64A, 64B and 64C are formed in the adhesion layer 73 (in this case, the resin layer is in a cured state). The resin member 37 including the opening parts 63A, 63B and 63C and the resin member 62 including the opening parts 64A, 64B, and 64C are formed.

The through-holes 82 are formed in the parts of the mask 81 facing the bottom side of the conductive material parts 36. The through-holes 83 are formed in the parts of the mask 81 facing the bottom sides of the electrodes 45. Further, the through-holes 84 are formed in the parts of the mask 81 facing the bottom sides of the electrodes 46.

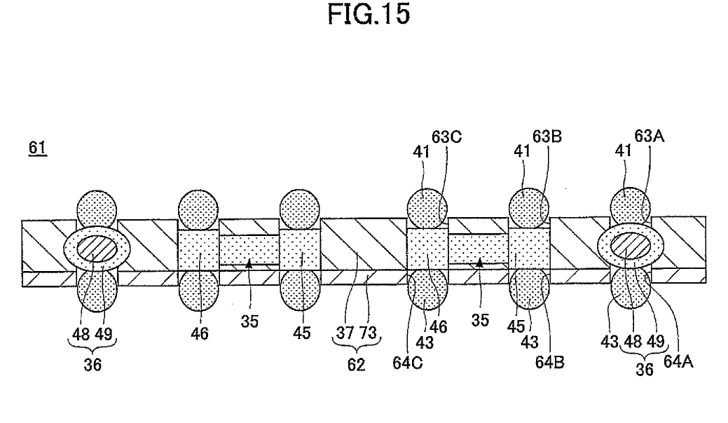

Next, in the process shown in FIG. 15, the external connection terminals 41 are formed on the upper side of the electrodes 45 and 46 and the upper side of the conductive material parts 36, and the external connection terminals 43 are formed on the bottom sides of the electrodes 45 and 46 and the bottom sides of the conductive material parts 36. With this, the electronic component built-in board 61 is manufactured. As the external connection terminals 41 and 43, for example, solder such as Sn—Ag—Cu solder may be used. In FIG. 15, although an example is given for use of the solder as the external connection terminals 41 and 43, by forming Au bumps (not shown) contacting the electrodes 45 and 46 or the conductive material parts 36 in the solder shown in FIG. 15, external connection terminals including Au bumps and solder covering the Au bumps may be formed.

### Second Embodiment

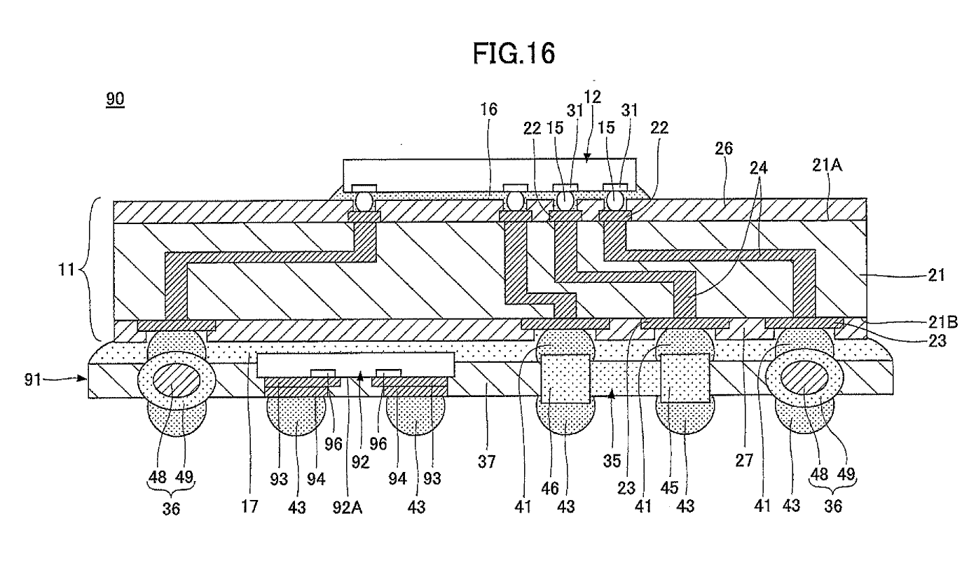

FIG. 16 is a cross section of the semiconductor device of the second embodiment of this invention. In FIG. 16, the identical symbols are used for the component parts which are identical to those of the semiconductor device 10 of the first embodiment.

Referring to FIG. 16, the semiconductor device 90 of the second embodiment is formed similarly to the semiconductor device 10 except that the electronic component built-in board 91 is provided instead of the electronic component built-in board 13 included in the semiconductor device 10 of the first embodiment.

The electronic component built-in board 91 is formed similarly to the electronic component built-in board 13 except that the electronic component 92, wiring (or wires) 93 and pads 94 are included in the electronic component built-in board 13 described in the first embodiment.

The sides of the electronic component 92 contact the resin part 37, so that the electronic component 92 is supported by the resin member 37. The electronic component 92 is an active element (active device) which includes electrode pads 96. For example, a semiconductor chip including less number of the electrode pads 96 (e.g. a memory semiconductor chip) may be used as an active element.

The wiring 93 is provided on the surface of the electronic component 92 of which the electrode pads 96 is formed. The wires of the wiring 93 are connected to the pads 94 and the electrode pads 96.

The wiring 93 is a wiring to electrically connect the electrode pads 96 and the pads 94 (rewiring). For example, Cu may be used as materials of the wiring 93.

The pads 94 are arranged on parts of the wiring 93 corresponding to the forming area of the external connection terminals 43. The pads 94 are provided to form the external connection terminals 43. The parts of the pads 94 to be connected to the external connection terminals 43 are exposed from the resin member 37. For example, Cu may be used as materials of the pads 94.

According to the electronic component built-in board of this embodiment, a passive element, the electronic components 35 and an active element, the electronic components 92 are formed in the resin member 37, so that an integration density of the electronic component built-in board 91 can be improved.

Further, the semiconductor device 90 of this embodiment can obtain a similar effect (advantage) of the semiconductor device 10 of the first embodiment.

As a substitute of the conductive material parts 36 formed in the electronic component built-in board 91, the conductive material parts 53 of FIG. 3 may be formed. Also, as substitutes of the resin member 37 formed in the electronic component built-in board 91, the resin member 62 of FIG. 4 may be formed.

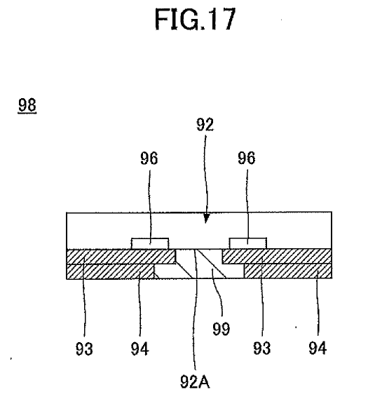

FIG. 17 is a cross section of a structure part used in a process where the electronic component built-in board of the second embodiment of this invention is manufactured. It is a cross section of a structure body.

In FIG. 17, with respect to parts identical to those of the electronic component built-in board 91, the same symbols used in the electronic component built-in board 91 are assigned.

In order to manufacture the electronic component built-in board 91 described above, the structure part 98 of FIG. 17 is formed in advance. Next, by the process of FIG. 6 described in the first embodiment, the electronic components 35, the conductive material parts 36, and the structure part 98 are provided on the adhesion layer 73. Thereafter, similar processes to those of FIG. 7 through FIG. 11 described in the first embodiment are performed to manufacture the electronic component built-in board 91.

Referring to FIG. 17, a description will be given for a manufacturing method of the structure part 98. The electronic components 92 having the electrode pads 96 are prepared first, then, the wiring 93 is formed on the surface 92A of the electronic components 92 at the side on which the electrode pads 96 are formed. The pads 94 are formed on the wiring 93. The resin layer 99 is formed on the surfaces 92A of the electronic components 92 for covering the wires of the wiring 93 and the pads 94. Next the structure part 98 is formed by removing parts of the resin layer 99 facing the pads 94 (for example, by a polishing process). For example, epoxy resin or mold resin may be used as materials of resin layer 99.

The resin layer 99 may be formed with the resin members 37 and 62 simultaneously while the resin members 37 and 62 are formed.

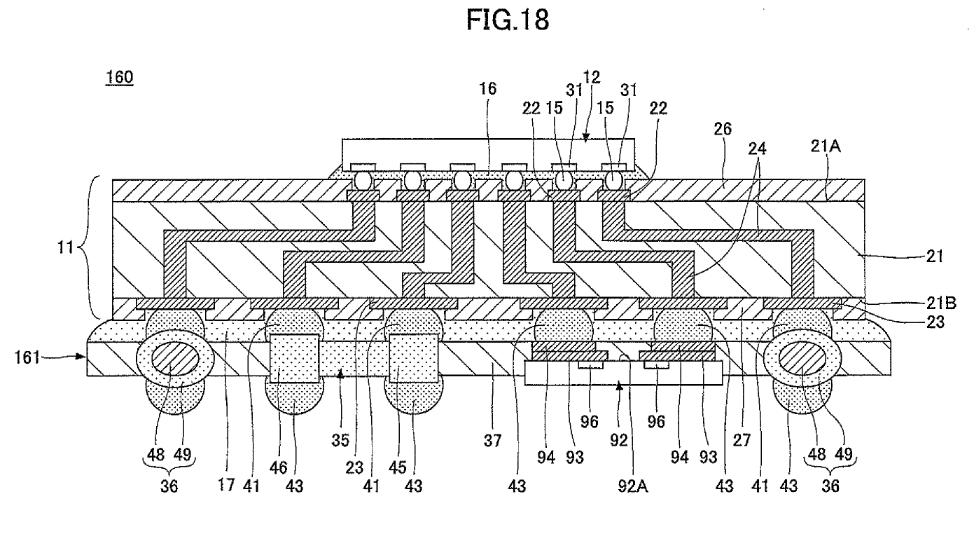

FIG. 18 is a cross section of the semiconductor device according to a modified example of the second embodiment of this invention. In FIG. 18, with respect to parts identical to those of the semiconductor device 90, the same symbols used in the semiconductor device 90 are assigned.

Referring to FIG. 18, the semiconductor device 160 of the modified example of the second embodiment is formed similarly to the semiconductor device 90 of the second embodiment except that the electronic component built-in board 161 is formed instead of the electronic component built-in board 91 which is formed in the semiconductor device 90 of the second embodiment.

The electronic component built-in board 161 is formed similarly to the electronic component built-in board 91 except that the forming areas of the electronic components 35 and the electronic components 92 formed in the electronic component built-in board 91 are replaced; the pads 94 electrically connected to the electrode pads 96 of the electronic components 92 are arranged to face the board connection pads 23; and the pads 94 are electrically connected to the board connection pads 23 via the external connection terminals 41.

In this way, by electrically connecting the pads 94 electrically connected to the electrode pads 96 of the electronic components 92 and the board connection pads 23 via the external connection terminals 41, the wiring length between the semiconductor chip 12 and the electronic components 92 is shortened, so that signal exchanges between the semiconductor chip 12 and the electronic components 92 can be performed at high speed.

### Third Embodiment

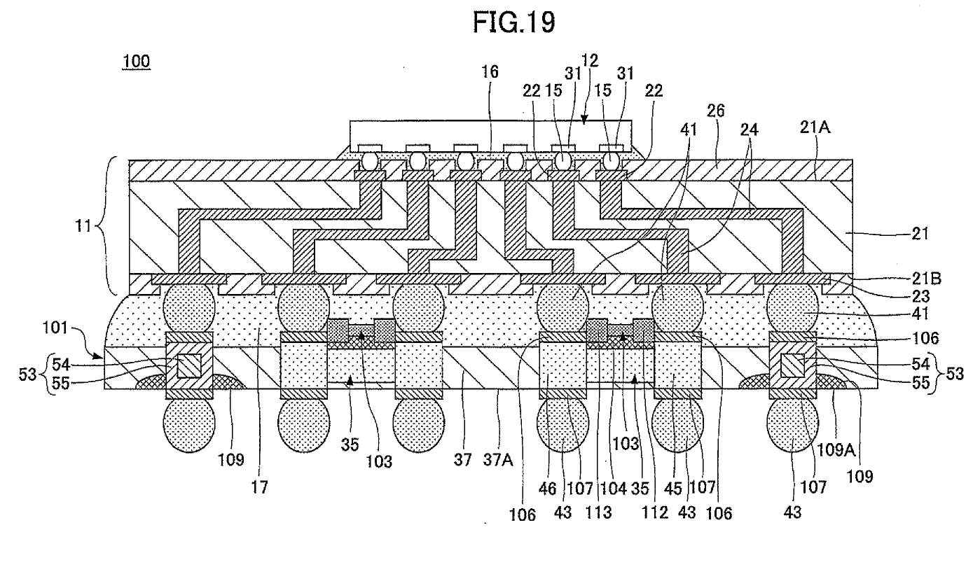

FIG. 19 is a cross section of the semiconductor device according to the third embodiment of this invention.

In FIG. 19, with respect to parts identical to those of the semiconductor device 50, the same symbols used in the semiconductor device are assigned to the parts.

Referring to FIG. 19, the semiconductor device 100 of the third embodiment is formed similarly to the semiconductor device 50 of the first modified example of the first embodiment except that the electronic component built-in board 101 is formed instead of the electronic component built-in board 51 which is formed in the semiconductor device 50 of the first embodiment.

The electronic component built-in board 101 is formed similarly to the electronic component built-in board 51 (FIG. 3) except that the electronic components 103, non-conductive materials 104 and 109 having the adhesive property, and conductive materials 106 and 107 are additionally provided in the structure of the electronic component built-in board 51.

The electronic components 103 are glued on part of the electronic components 35 except the electrodes 45 and 46 by the non-conductive material 104 having the adhesion nature. The electronic components 103 are smaller than the electronic components 35 (specifically, height and an area in a plane view). The electronic components 103 include a pair of electrodes 112 and 113.

The electrodes 112 contact the conductive material 106. The electrodes 112 are electrically connected to the electrodes 45 and the external connection terminals 41 via the conductive material 106 formed on the upper sides of the electrodes 45. The electrodes 113 are electrically connected to the electrodes 46 and the external connection terminals 41 via the conductive material 106 formed on the upper side of the electrodes 46. With this, the electronic components 103 are electrically connected to the electronic components 35, and electrically connected to the semiconductor chip 12 via the wiring board 11.

In this way, the integration density of the electronic component built-in board 101 can be improved by mounting the electronic components 103 on the electronic components 35.

For example, a passive element may be used as the electronic components 103. When chip capacitors are used as the electronic components 35, the chip capacitors may be used as the electronic components 103.

In this way, the chip capacitors are used as the electronic components 35 and 103, the electronic components 103 are mounted on the electronic components 35, and the electronic components 103 and the electronic components 35 are electrically connected, so that the capacitance of the capacitor becomes larger.

The non-conductive material 104 is arranged between the electronic components 35 and the electronic components 103. The non-conductive material 104 is used to glue the electronic components 103 on the electronic components 35. For example, underfill resin may be used as the non-conductive material 104.

The conductive materials 106 are formed on the upper sides of the electrodes 45 and 46 and the upper sides of the conductive material parts 53. The external connection terminals 41 are provided on the front surface of the conductive materials 106. The conductive materials 106 provided on the electrodes 45 electrically connect the external connection terminals 41, the electrodes 112 of the electronic components 103 and the electrodes 45. The conductive materials 106 provided on the electrodes 46 electrically connect the external connection terminals 41, the electrodes 113 of the electronic components 103 and the electrodes 46. The conductive materials 106 provided on the upper sides of the conductive material parts 53 electrically connect the external connection terminals 41 and the conductive material parts 53. For example, electroconductive paste or solder may be used as the conductive materials 106. For example, Ag paste may be used as the electroconductive paste. For example, Sn—Ag—Cu solder may be used as the solder. When the solder is used as the conductive materials 106, the thickness of the conductive materials 106 may be approximately 30 μm.

The conductive materials 107 are formed on the bottom sides of the electrodes 45 and 46 and on the bottom sides of the conductive material parts 53. The external connection terminals 43 are provided on the rear surface of the conductive materials 107. The conductive materials 107 are electrically connected to the external connection terminals 43. For example, electroconductive paste or solder may be used as the conductive materials 107. For example, Ag paste may be used as the electroconductive paste. For example, Sn—Ag—Cu solder may be used as the solder. When the solder is used as the conductive materials 107, for example, the thickness of the conductive materials 107 may be approximately 30 μm.

The non-conductive material 109 is formed in the resin member 37 to cover the lower and side parts of the conductive material parts 53. The rear surfaces 109A of the non-conductive material 109 are arranged so as to be approximately in the identical plane to the rear surfaces 37A of the resin member 37. For example, underfill resin may be used as the non-conductive material 109.

According to the electronic component built-in board of this embodiment, the integration density of the electronic component built-in board 101 can be improved by mounting the electronic components 103 on the electronic components 35.

Also, according to the semiconductor device of this embodiment, the integration density of the semiconductor device 100 can be improved by providing the electronic component built-in board 101 whose integration density is improved. Further, the semiconductor device 100 of this embodiment can obtain a similar effect (advantage) to that of the semiconductor device 50 of the first modified example of the first embodiment.

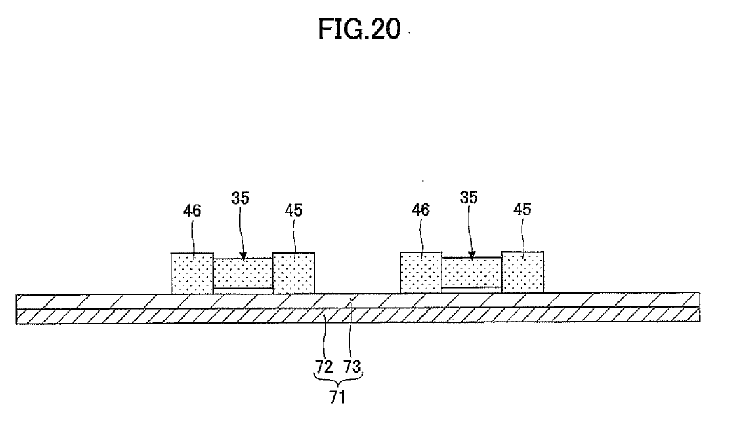

FIG. 20 through FIG. 27 are drawings showing a manufacturing process of the electronic component built-in board according to the third embodiment of the present invention.

In FIG. 20 through FIG. 27, the identical symbols are used for the component parts which are identical to those of the electronic component built-in board 101 of the third embodiment (shown in FIG. 19).

Referring to FIG. 20 through FIG. 27, a description will be given for the manufacturing method of the electronic component built-in board 101 of the third embodiment. In the process shown in FIG. 20, the electronic components 35 are provided on the support member 71 of FIG. 5 described in the first embodiment.

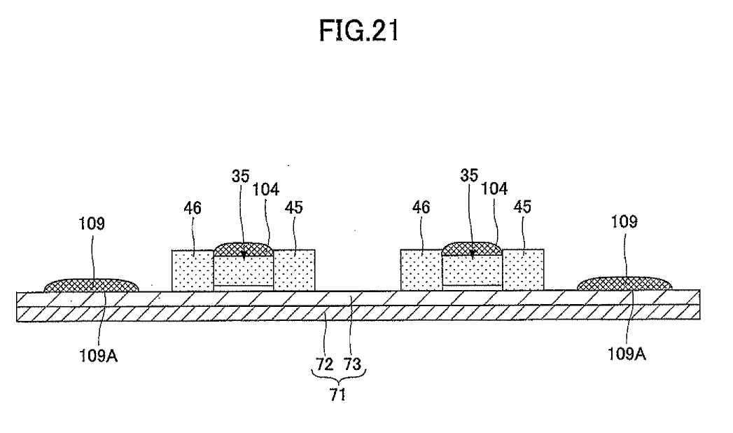

In the process shown in FIG. 21, the non-conductive material 104 is formed on the electronic components 35 and, the non-conductive material 109 is formed on parts of the adhesion layer 73 corresponding to the forming area of the conductive material parts 53. For example, underfill resin may be used as the non-conductive materials 104 and 109.

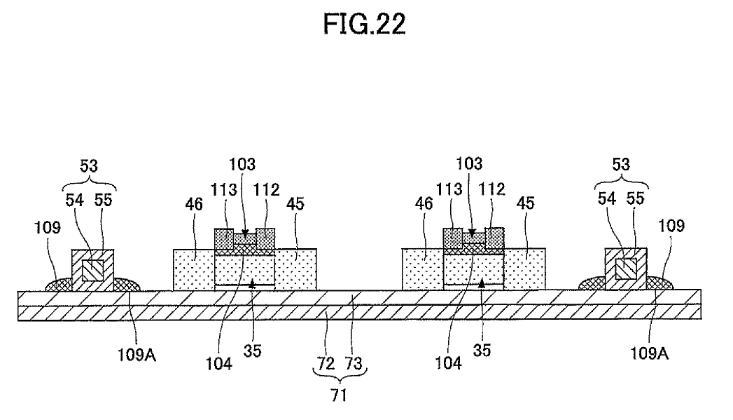

Next, in the process shown in FIG. 22, the electronic components 103 are glued on the electronic components 35 with the non-conductive material 104, and the conductive material parts 53 are arranged on the adhesion layer 73 so that the rear surfaces of the conductive material parts 53 contact the front surface of the adhesion layer 73. In the case of this embodiment, the processes shown in FIG. 20 through FIG. 22 correspond to the arrangement process of electronic components and conductive material parts.

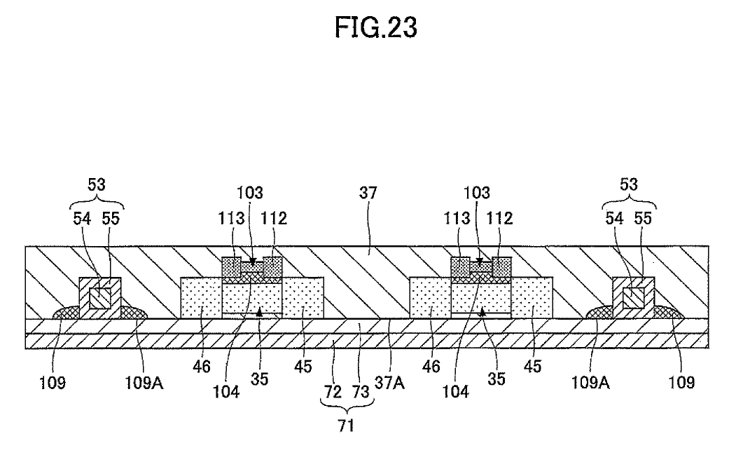

Next, in the process shown in FIG.23, the resin member 37 is formed on the front surface of the adhesion layer 73 so as to cover at least the sides of the electronic components 35 and the sides of the conductive material parts 53 (a resin member formation process). Specifically, the resin member 37 is formed by mounting a resin tablet (not shown) on the structure part shown in FIG. 22 and pressing the resin tablet with a flat metal plate (not shown). At this stage, the upper sides of the electronic components 35 and 103 and the upper sides of the conductive material parts 53 are covered with the resin member 37. Thickness of the resin member 37 shown in FIG. 23 is thicker than that of the resin member 37 shown in FIG. 19. In this embodiment, a description will be given below for an example case where the resin member 37 is formed so as to cover the electronic components 35 and 103 and the conductive material parts 53. Further, in the process shown in FIG. 23, the resin member 37 may be formed so as to expose the upper sides of the electronic components 103, the upper sides of the electrodes 45 and 46, and the upper sides of the conductive material parts 53.

For example, epoxy resin or mold resin may be used as a material of the resin tablet described above. When the mold resin (a content of silicone filler or, filler of aluminum is high, for example, 70 wt % through 80 wt %) is used as the material of the resin member 37, the difference of the thermal expansion coefficient between the electronic components 35 and the resin member 37 can be decreased.

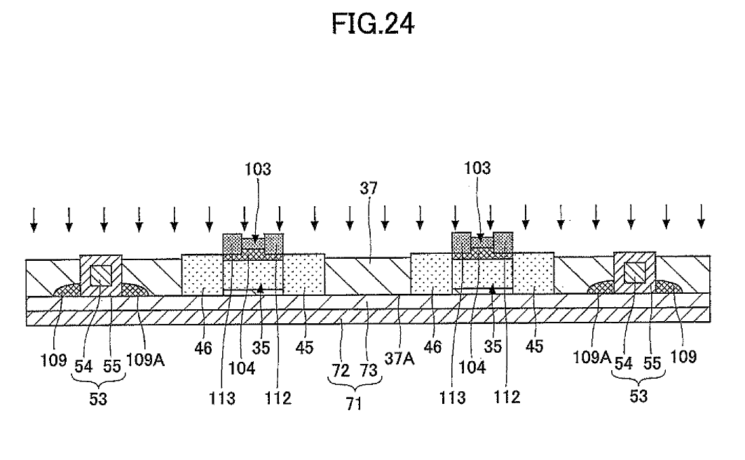

Next, in the process shown in FIG. 24, the electronic components 103, the upper sides of the electrodes 45 and 46, and the upper sides of the conductive material parts 53 are exposed from the resin member 37 by removing the whole upper part of the resin member 37 of FIG. 23 (the resin member removal process). Specifically, the electronic components 103, the upper sides of the electrodes 45 and 46, and the upper sides of the conductive material parts 53 are exposed from the resin member 37 by performing the ashing process for the resin member 37 of FIG. 23 from the front surface of the resin member 37.

The ashing process above may be performed, for example, by use of oxygen (O₂) gas having a purity of 99.99% (the oxygen gas may be mixed with argon (Ar) gas and carbon fluoride gas such as CF₄), with a gas flow rate of 500 sccm at radio frequency (RF) power of approximately 350 W at a frequency of 13.56 MHz under a pressure of approximately 133 Pa at a temperature ranging from approximately 90° C. to 120° C. in the process chamber. In this case, the process time may be approximately 15 min.

In this way, by removing the whole upper part of the resin member 37 with the ashing process, the electronic components 103, the upper sides of the electrodes 45 and 46 and the upper sides of the conductive material parts 53 can be exposed from the resin member 37 without causing damage to the electronic components 35 and 103, and the conductive material parts 53.

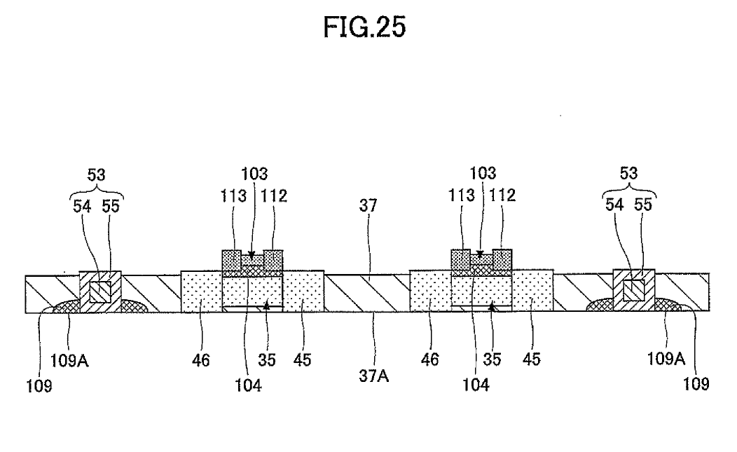

In the process shown in FIG. 25, the support member 71 of FIG. 24 is removed (the support member removal process). Specifically, for example, the support member 71 is taken off from the resin member 37.

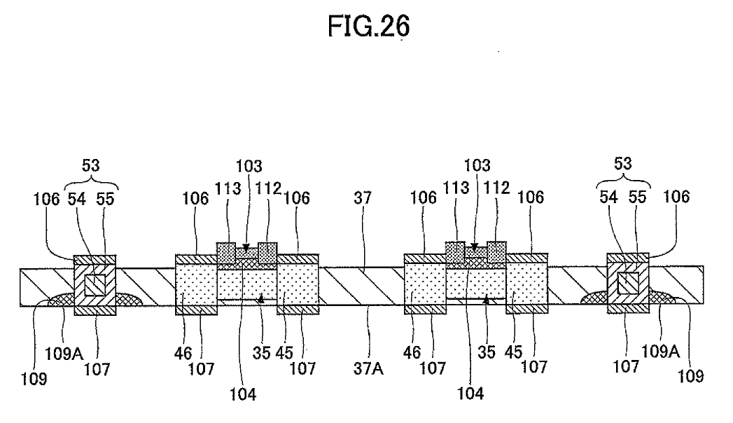

Next, in the process shown in FIG. 26, the conductive materials 106 is formed so as to cover the upper sides of the electrodes 45 and 46 and the upper sides of the conductive material parts 53, and the conductive materials 107 is formed so as to cover the bottom sides of the electrodes 45 and 46 and the bottom sides of the conductive material parts 53. For example, electroconductive paste or solder may be used as the conductive materials 106 and 107. For example, Ag paste may be used as the electroconductive paste. For example, Sn—Ag—Cu may be used as the solder. When Ag paste is used as the conductive materials 106 and 107, for example, the thickness of the conductive materials 106 and 107 may be approximately 30 μm.

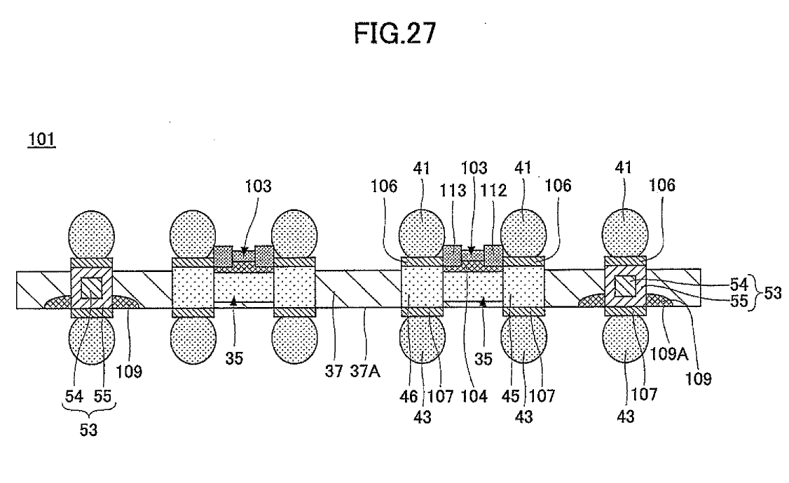

Next, in the process shown in FIG. 27, the external connection terminals 41 are formed on the upper sides of the electrodes 45 and 46 and the upper sides of the conductive material parts 53, and the external connection terminals 43 are formed on the bottom sides of the electrodes 45 and 46 and the bottom sides of the conductive material parts 53. With this, the electronic component built-in board 101 is manufactured. For example, solder may be used as the external connection terminals 41 and 43 (for example, Sn—Ag—Cu solder). In FIG. 27, although an example is given for a case where the solder is used for the external connection terminals 41 and 43, the external connection terminals 41 and 43 including Au bumps and solder covering the Au bumps may be formed by providing Au bumps contacting the electrodes 45 and 46 or the conductive material parts 53 in the solder of FIG. 27.

According to the manufacturing method of the electronic component built-in board of this embodiment, the electronic components 103 is glued on the electronic components 35 arranged on the support member 71, and the conductive material parts 53 are provided on the support member 71. Next, the resin member 37 is formed so as to cover at least the sides of the electronic components 35 and the sides of the conductive material parts 53. Further, the electronic components 103, the upper sides of the electrodes 45 and 46 and the upper sides of the conductive material parts 53 are exposed from the resin member 37, and then the support member 71 is removed. The conductive materials 106 are formed on the upper sides of the electrodes 45 and 46 and the upper sides of the conductive material parts 53, and the conductive materials 107 are formed on the bottom sides of the electrodes 45 and 46 and the bottom sides of the conductive material parts 53. Next, the external connection terminals 41 are formed on the conductive materials 106, and the external connection terminals 43 are formed on the conductive materials 107. In this way, the electrical connection reliability of the electronic component built-in board 101 can be improved. Further, the electronic component built-in board 101 can be downsized in the thickness direction, and thus the integration density of the electronic component built-in board 101 can be improved.

### Fourth Embodiment

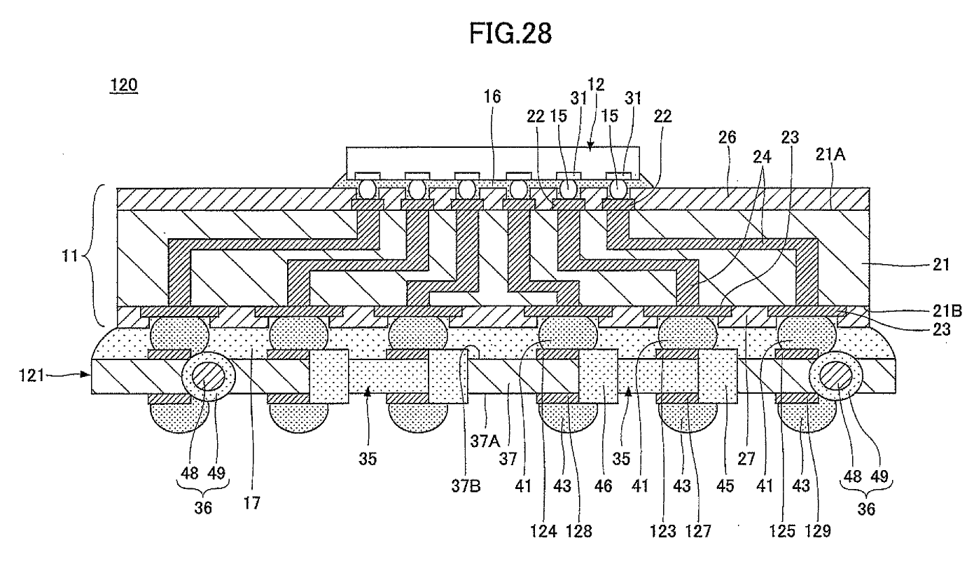

FIG. 28 is a cross section of the semiconductor device according to the fourth embodiment of this invention. In FIG. 28, with respect to parts identical to those of the semiconductor device 10 of the first embodiment, the same symbols are used.

Referring to FIG. 28, the semiconductor device 120 of the fourth embodiment is formed similarly to the semiconductor device 10 of the first embodiment except that the electronic component built-in board 121 is formed instead of the electronic component built-in board 13 (see FIG. 2) which is formed in the semiconductor device 10 of the first embodiment.

The electronic component built-in board 121 is formed similarly to the electronic component built-in board 13 except that upper pads 123, 124 (the first upper pads), upper pads 125 (the second upper pads), lower pads 127, 128 (the first lower pads) and lower pads 129 (the second lower pads) are further formed with the electronic component built-in board 13.

The upper pads 123 are formed on the front surfaces of the electronic components 35 located between the electrodes 45 and the electrodes 46 so as to contact the upper parts of the electrodes 45.

In this way, by forming the upper pads 123 on the front surfaces of the electronic components 35 which contact the upper parts of the electrodes 45, the degradation of electrical connection reliability between the board connection pads 23 and the electrodes 45 can be prevented when relative misalignment occurs between the board connection pads 23 and the electrodes 45 (such as misalignment due to variation of shapes of the electronic components 35).

In FIG. 28, although a description is given for an example case where the external connection terminals 41 (in this case, the first external connection terminals) are arranged so as to contact the upper sides of the electrodes 45 and the front surfaces of the upper pads 123, the external connection terminals 41 may be formed so as to contact only the upper sides of the electrodes 45 or may be formed so as to contact only the front surfaces of the upper pads 123.

The upper pad 124 is formed on the front surface 37B of the resin member 37 so as to contact the upper part of the electrode 46.

In this way, by forming the upper pads 124 on the front surfaces 37B of the resin member 37 contacting the upper parts of the electrodes 46, the degradation of electrical connection reliability between the board connection pads 23 and the electrodes 46 can be prevented when relative misalignment occurs between the board connection pads 23 and the electrodes 46 (such as misalignment due to variation of shapes of the electronic components 35).

In FIG. 28, although a description is given for an example case where the external connection terminals 41 (in this case, the first external connection terminals) are arranged so as to contact the upper sides of the electrodes 46 and the front surfaces of the upper pads 124, the external connection terminals 41 may be formed so as to contact only the upper sides of the electrodes 46 or may be formed so as to contact only the front surfaces of the upper pads 124.

The upper pads 125 are formed on the front surfaces 37B of the resin member 37 so as to contact the upper parts of the conductive material parts 36.

In this way, by forming the upper pads 125 on the front surfaces 37B of the resin member 37 contacting the upper parts of the conductive material parts 36, the degradation of electrical connection reliability between the board connection pads 23 and the conductive material parts 36 can be prevented when relative misalignment occurs between the board connection pads 23 and the conductive material parts 36 (such as a case where the conductive material parts 36 are misaligned from predetermined positions while the electronic component built-in board 121 is formed).

In FIG. 28, although a description is given for an example case where the external connection terminals 41 (in this case, the second external connection terminals) are arranged so as to contact the upper sides of the conductive material parts 36 and the front surfaces of the upper pads 125, the external connection terminals 41 may be formed so as to contact only the upper sides of the conductive material parts 36 or may be formed so as to contact only the front surfaces of the upper pads 125.

As the upper pads 123-125, for example, an Ni/Cu stacked layer formed by sequentially stacking an Ni layer and a Cu layer, a Ti/Cu stacked layer formed by sequentially stacking a Ti layer and a Cu layer, or a Cr/Cu stacked layer formed by sequentially stacking a Cr layer and a Cu layer may be used.

The lower pads 127 are formed on parts of the rear surfaces of the electronic components 35 located between the electrodes 45 and the electrodes 46 so as to contact the lower sides of the electrodes 45. In this way, by forming the lower pads 127 on the rear surfaces of the electronic components 35 contacting the lower parts of the electrodes 45, the degradation of electrical connection reliability between the pads of a mounting board (such as a mother board, not shown) and the electrodes 45 can be prevented when relative misalignment occurs between the pads of the mounting board and the electrodes 45 (such as misalignment due to variation of shapes of the electronic components 35).

In FIG. 28, although a description is given for an example case where the external connection terminals 43 (in this case, the third external connection terminals) are arranged so as to contact the bottom sides of the electrodes 45 and the rear surfaces of the lower pads 127, the external connection terminals 43 may be formed so as to contact only the bottom sides of the electrodes 45 or may be formed so as to contact only the rear surfaces of the lower pads 127.

The lower pads 128 are formed on the rear surfaces 37A of the resin member 37 so as to contact the lower sides of the electrodes 46.

In this way, by forming the lower pads 128 on the rear surfaces 37A of the resin member 37 contacting the lower sides of the electrodes 46, the degradation of electrical connection reliability between the pads of a mounting board (such as a mother board, not shown) and the electrodes 46 can be prevented when relative misalignment occurs between the pads of the mounting board and the electrodes 46 (such as misalignment due to variation of shapes of the electronic components 35).

In FIG. 28, although a description is given for an example case where the external connection terminals 43 (in this case, the third external connection terminals) are arranged so as to contact the bottom sides of the electrodes 46 and the rear surfaces of the lower pads 128, the external connection terminals 43 may be formed so as to contact only the bottom sides of the electrodes 46 or may be formed so as to contact only the rear surfaces of the lower pads 128.

The lower pads 129 are formed on the rear surfaces 37A of the resin member 37 so as to contact the lower sides of the conductive material parts 36.

In this way, by forming the lower pads 129 on the rear surfaces 37A of the resin member 37 contacting the lower sides of the conductive material parts 36, the degradation of electrical connection reliability between the pads of a mounting board (such as a mother board, not shown) and the conductive material parts 36 can be prevented when relative misalignment occurs between the pads of the mounting board and the conductive material parts 36 (such as a case where the conductive material parts 36 are misaligned from predetermined positions while the electronic component built-in board 121 is formed).

In FIG. 28, although a description is given for an example case where the external connection terminals 43 (in this case, the fourth external connection terminals) are arranged so as to contact the lower sides of the conductive material parts 36 and the rear surfaces of the lower pads 129, the external connection terminals 43 may be formed so as to contact only the lower sides of the conductive material parts 36 or may be formed so as to contact only the rear surfaces of the lower pads 129.

As the lower pads 127-129, for example, a Ni/Cu stacked layer formed by sequentially stacking an Ni layer and a Cu layer, a Ti/Cu stacked layer formed by sequentially stacking a Ti layer and a Cu layer, or a Cr/Cu stacked layer sequentially stacking a Cr layer and a Cu layer may be used.

According to the electronic component built-in board of this embodiment, the upper pads 123 are formed on the front surface of the electronic components 35 so as to contact the upper part of the electrodes 45, the upper pads 124 are formed on the front surface 37B of the resin member 37 so as to contact the upper part of the electrodes 46, and the upper pads 125 are formed on the front surface 37B of the resin member 37 so as to contact the upper part of the conductive material parts 36. With this, the degradation of the electrical connection reliability between the board connection pads 23 and the electrodes 45 and 46, and the conductive material parts 36 can be prevented when relative misalignment between the board connection pads 23 and the electrodes 45 and 46 occurs, or when a relative misalignment between the board connection pads 23 and the conductive material parts 36 occurs.

Further, the lower pads 127 are formed on the rear surfaces of the electronic components 35 contacting the lower sides of the electrodes 45, the lower pads 128 are formed on the rear surfaces 37A of the resin member 37 contacting the lower sides of the electrodes 46, and the lower pads 129 are formed on the rear surfaces 37A of the resin member 37 contacting the lower sides of the conductive material parts 36. With this, the degradation of electrical connection reliability between the pads of the mounting board and the electrodes 45 and 46 and between the pads of the mounting board and the conductive material parts 36 can be prevented when relative misalignment occurs between the pads of the mounting board (such as a mother board, not shown) and the electrodes 45 and 46 or when relative misalignment occurs between the pads of the mounting board (such as a mother board, not shown) and the conductive material parts 36.

According to the semiconductor device of this embodiment, by providing the electronic component built-in board 121 formed by the structure described above, the electrical connection reliability of the semiconductor device 120 can be improved, and the electrical connection reliability between the semiconductor device 120 and a mounting board (such as a mother board, not shown) electrically connected to the semiconductor device 120 and the conductive material parts 36 can be prevented.

Further, instead of the conductive material parts 36 provided for the electronic component built-in board 121 of this embodiment, the conductive material parts 53 described above (see FIG. 19) may be provided.

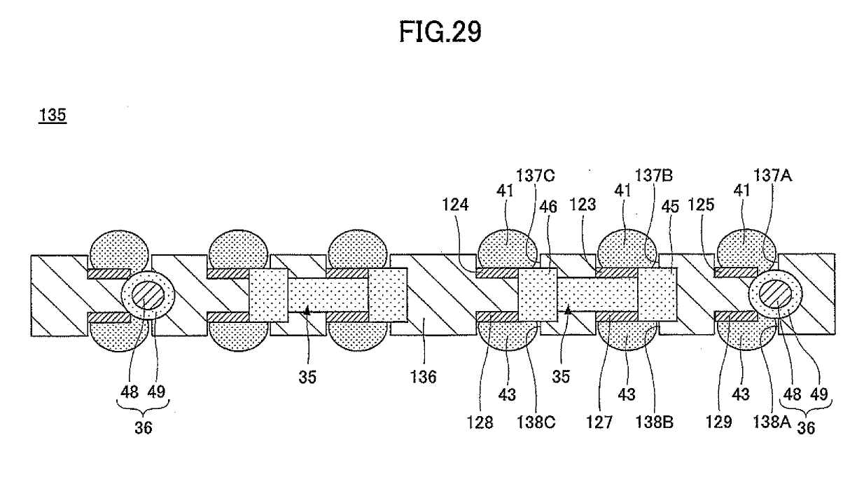

FIG. 29 is a cross section of the electronic component built-in board according to a modified example of the fourth embodiment of this invention.

Referring to FIG. 29, an electronic component built-in board 135 of the modified example of the fourth embodiment is formed similarly to the electronic component built-in board 121 except that a resin member 136 is provided instead of the resin member 37 provided for the electronic component built-in board 121 of the fourth embodiment.

The resin member 136 is formed similarly to the resin member 37 except that opening parts 137A, 137B, 137C, 138A, 138B and 13SC are formed, and their profiles are thicker than that of the resin member 37.

The opening part 137A is formed to expose the front surface of the upper pad 125 and part of the upper side of the conductive material part 36. The opening part 137B is formed to expose the front surface of the upper pad 123 and part of the upper side of the conductive material part 45. The opening part 137C is formed to expose the front surface of the upper pad 124 and part of the upper side of the conductive material part 46. The opening parts 137A, 137B, 137C accommodate parts of the external connection terminals 41.

The opening part 138A is formed to expose the rear surface of the lower pad 129 and part of the bottom side of the conductive material parts 36. The opening part 138B is formed to expose the rear surface of the lower pad 127 and part of the bottom side of the conductive material part 45. The opening part 138C is formed to expose the rear surface of the lower pad 128 and part of the bottom side of the electrodes 46. The opening parts 138A, 138B, 138C accommodate parts of the external connection terminals 43.

According to the electronic component built-in board of the modified example of this embodiment, the opening parts 137A, 137B, and 137C accommodating parts of the external connection terminals 41 are formed in the resin member 136 whose profile is thicker than the resin member 37, so the parts of the resin member 136 of the opening parts 137A, 137B and 137C regulate positions of the external connection terminals 41, and thus the adjacent external connection terminals 41 can be prevented from short circuiting.

Further, the opening parts 138A, 138B, and 138C accommodating parts of the external connection terminals 43 are formed in the resin member 136 whose profile is thicker than the resin member 37, so the parts of the resin member 136 of the opening parts 138A, 138B and 138C regulate positions of the external connection terminals 43, and thus the adjacent external connection terminals 43 can be prevented from short circuiting.

Instead of the conductive material parts 36 formed in the electronic component built-in board 135 of this embodiment, the conductive material parts 53 described in FIG. 19 may be formed.

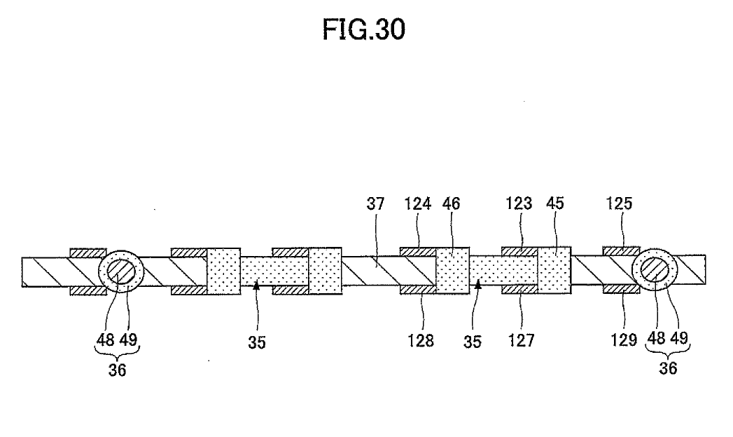

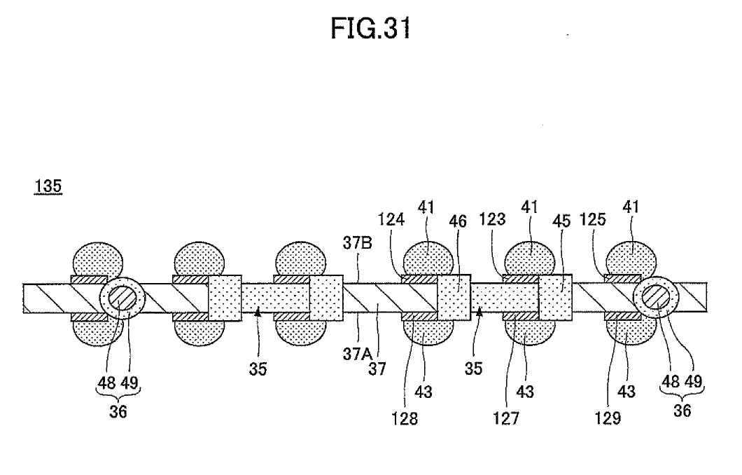

FIG. 30 and FIG. 31 are drawings showing a manufacturing process of the electronic component built-in board according to the fourth embodiment of this invention. In FIG. 30 and FIG. 31, with respect to parts which are identical to those used in the electronic component built-in board 121 of the fourth embodiment, the same symbols are assigned.

Referring to FIG. 30 and FIG. 31, a description will be given for a manufacturing method of the electronic component built-in board 135 of the fourth embodiment. Firstly, processes similar to those of FIG. 5 through FIG. 10 described in the first embodiment are performed.

In the process shown in FIG. 30, the upper pads 123-125 and the lower pads 127-129 are formed (the upper pads and lower pads formation process). Specifically, for example, the upper pads 123-125 and the lower pads 127-129 may be formed by a semi-additive method. In this case, an Ni/Cu stacked layer formed by sequentially stacking an Ni layer (for example, approximately 5 μm thick) and a Cu layer (for example, approximately 3 μm thick) may be used as the upper pads 123-125 and the lower pads 127-129.

Further, the upper pads 123-125 and the lower pads 127-129 may be formed by etching formed metal films. As the lower pads 123-125, for example, a Ti/Cu stacked layer formed by sequentially stacking a Ti layer (for example, approximately 0.1 μm thick) and a Cu layer (for example, approximately 0.5 μm thick) or a Cr/Cu stacked layer formed by sequentially stacking a Cr layer (for example, approximately 0.1 μm thick) and a Cu layer (for example, approximately 0.5 μm thick) may be used.

In the process shown in FIG. 30, at least one of the upper pads and one of the lower pads with respect to the upper pads 123-125 and the lower pads 127-129 may be formed.

In the process shown in FIG. 31, the external connection terminals 41 and 43 may be formed. With this, the electronic component built-in board 135 is manufactured.

According to the manufacturing method of the electronic component built-in board of this embodiment, by forming the upper pads 123-125 before forming the external connection terminals 41, it becomes possible that part or all of the external connection terminals 41 are mounted on the upper pads 123-125 even if the forming area of the external connection terminals 41 is misaligned, and thus the electrical connection reliability of the electronic component built-in board 135 can be improved.

Further, by forming the lower pads 127-129 before forming the external connection terminals 43, it becomes possible that part or all of the external connection terminals 43 are mounted on the lower pads 127-129 even if the forming area of the external connection terminals 43 is misaligned, and thus the electrical connection reliability of the electronic component built-in board 135 can be improved.

### Fifth Embodiment

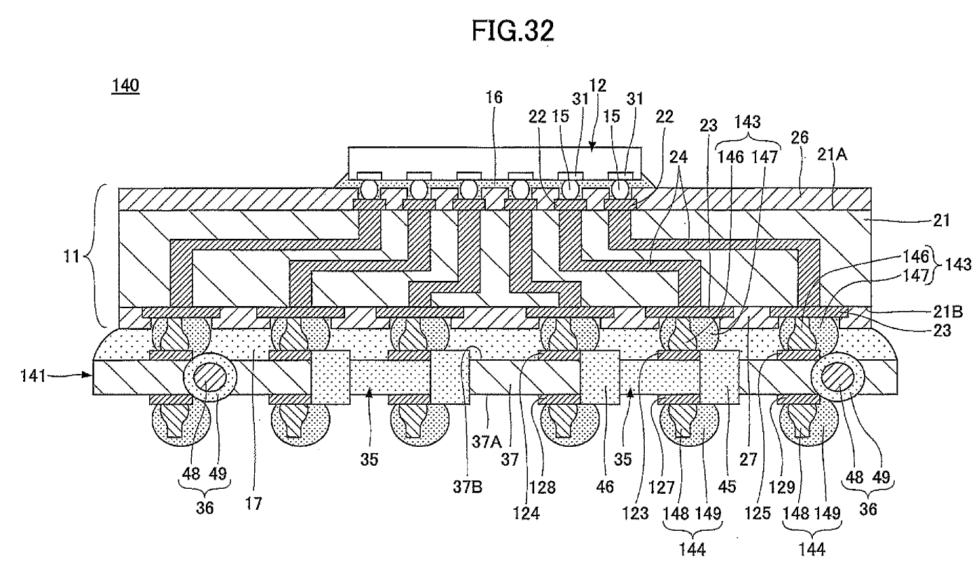

FIG. 32 is a cross section of the semiconductor device according to the fifth embodiment of this invention. In FIG. 32, parts identical to those of the semiconductor device 120 of the fourth embodiment are identified by identical symbols.

Referring to FIG. 32, a semiconductor device 140 of the fifth embodiment is formed similarly to the semiconductor device 120 of the fourth embodiment except that an electronic component built-in board 141 is provided instead of the electronic component built-in board 121 formed in the semiconductor device 120 of the fourth embodiment.

The electronic component built-in board 141 is formed similarly to the electronic component built-in board 121 except that external connection terminals 143 and 144 are provided instead of the external connection terminals 41 and 43 formed in the electronic component built-in board 121.

In the present embodiment, the first external connection terminals are the external connection terminals 143 formed so as to contact the upper sides of the electrodes 45 and the front surface of the upper pads 123, and the external connection terminals 143 formed so as to contact the upper sides of the electrodes 46 and the front surface of the upper pads 124. The second external connection terminals are the external connection terminals 143 formed so as to contact the upper sides of the conductive material parts 36 and the front surface of the upper pads 125.

Further, the third external connection terminals are the external connection terminals 144 formed so as to contact the bottom sides of the electrodes 45 and the rear surfaces of the lower pads 127, and the external connection terminals 144 formed so as to contact the bottom sides of the electrodes 46 and the rear surfaces of the lower pads 128. The fourth external connection terminals are the external connection terminals 144 formed so as to contact the bottom sides of the conductive material parts 36 and the rear surfaces of the lower pads 129.

The external connection terminals 143 include Au bumps 146 and solder 147. The Au bumps 146 are arranged on the upper pads 123-125. The upper sides of the Au bumps 146 are connected to the board connection pads 23. The solder 147 is formed between the board connection pads 23 and the upper pads 123-125 so as to cover the side of the Au bumps 146. For example, solder (for example, Sn—Ag—Cu solder) may be used as the solder 147.

The external connection terminals 144 include Au bumps 148 and solder 149. The Au bumps 148 are arranged on the lower pads 127-129. The lower sides of the Au bumps 148 are connected to the pads of a mounting board (such as a mother board, not shown). The solder 149 is formed on the lower pads 127-129 so as to cover the Au bumps 148. For example, solder (for example, Sn—Ag—Cu solder) may be used as the solder 149.

According to the electronic component built-in board of this embodiment, the external connection terminals 143 including the Au bumps 146 and the solder 147 are provided, and the upper sides of the Au bumps 146 are electrically connected to the board connection pads 23 via the external connection terminals 143. With this, the electrical connection reliability between the wiring board 11 and the electronic component built-in board 141 can be improved.

The external connection terminals 144 including the Au bumps 148 and the solder 149 are provided, and a mounting board (such as a mother board, not shown) and the electronic component built-in board 141 are connected via the external connection terminals 144. With this, the electrical connection reliability between the mounting board (not shown) and the electronic component built-in board 141 can be improved.

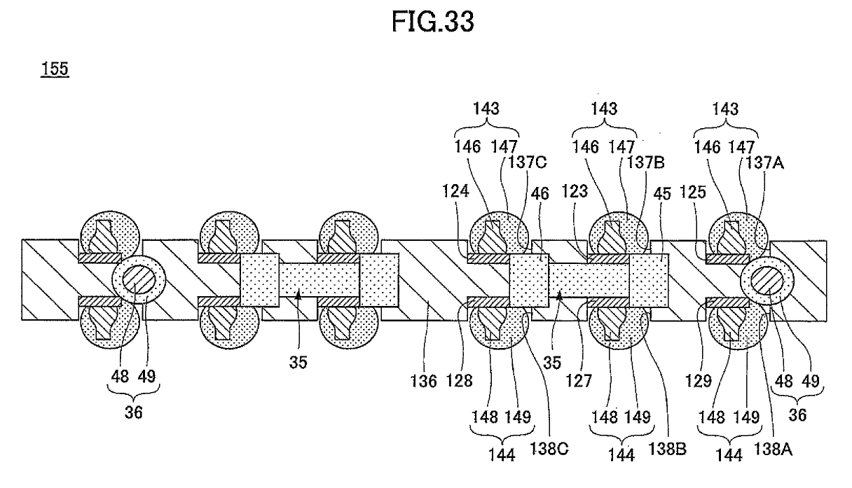

FIG. 33 is a cross section of the electronic component built-in board according to a modified example of the fifth embodiment of this invention. In FIG. 33, parts identical to those of the electronic component built-in board 141 of the fifth embodiment are identified by identical reference symbols.

Referring to FIG. 33, an electronic component built-in board 155 of the modified example of the fifth embodiment is formed similarly to the electronic component built-in board 141 except that the resin member 136 included the electronic component built-in board 135 of the modified example of the fourth embodiment (see FIG. 29) is provided instead of the resin member 37 formed in the electronic component built-in board 141 of the fifth embodiment.

The electronic component built-in board 155 formed as described above can obtain a similar effect to that of the electronic component built-in board 141 of the fifth embodiment.

According to this invention, the electronic component built-in board includes the electronic components having the electrodes, the conductive material parts arranged in the identical plane to that of the electronic components, and the resin member supporting the electronic components and the conductive material parts and exposing the upper sides and bottom sides of the electrodes, the upper sides and the bottom sides and the conductive material parts. With this, compared to the related art electronic component built-in board including the wiring patterns electrically connected to the insulating layer and the electronic components on the upper side and rear side of the electronic components, the electrical connection reliability of the electronic component built-in board can be improved, and the electronic component built-in board can be downsized in the thickness direction.

According to this invention, the electrical connection reliability of the semiconductor device can be improved, and the semiconductor device can be downsized in the thickness direction.

According to this invention, the electronic components and the conductive material parts are provided on the support member, and the resin member is formed so as to cover at least the side of the electronic components and the side of the conductive material parts. Further, the upper sides of the electrodes and the upper sides of the conductive material parts are exposed from the resin member, and then the support member is removed. With this manufacturing process, the electrical connection reliability of the electronic component built-in board can be improved, and the electronic component built-in board can be downsized in the thickness direction.

According to this invention, the electrical connection reliability of the electronic component built-in board can be improved and the electronic component built-in board can be downsized in the thickness direction.

Although the invention has been described with respect to specific embodiments for a complete and clear disclosure, the appended claims are not to be thus limited but are to be construed as embodying all modifications and alternative constructions that may occur to one skilled in the art that fairly fall within the basic teachings herein set forth.

For example, Ag paste or solder may be provided on the electrodes 45 and 46 of the electronic components 35 and the conductive material parts 35 and 53. With this, the external connection terminals 41 having various diameters can be mounted on the electrodes 45 and 46 of the electronic components 35 and the conductive material parts 35 and 53 via the Ag paste.

Further, the conductive material parts 36 and 53 may be used as electrical lines when necessary.

The present invention may be applied to an electronic component built-in board including electronic components, a manufacturing method thereof and a semiconductor device.

This patent application is based on Japanese Priority Patent Application No. 2008-068532 filed on Mar. 17, 2008, the entire contents of which are hereby incorporated by reference.

What is claimed is:

1. An electronic component built-in board comprising:
an electronic component having an electrode;
a conductive material part arranged in an identical plane to the electronic component; and
a resin member configured to support the electronic component and the conductive material part in a state where an upper side and a bottom side of the electronic component and an upper side and a bottom side of the conductive material part are exposed.

2. The electronic component built-in board as claimed in claim 1, wherein the resin member has a plate-shaped configuration; and
the resin member has a thickness of the resin member greater than a height of the electronic component and a height of the conductive material part.

3. The electronic component built-in board as claimed in claim 1, wherein a material of the resin member is mold resin.

4. The electronic component built-in board as claimed in claim 1, wherein external connection terminals are formed onto the upper side and the bottom side of the electrode and onto the upper side and the bottom side of the conductive material part.

5. The electronic component built-in board as claimed in claim 4, wherein the external connection terminals include Au bumps and solder covering the Au bumps.

6. The electronic component built-in board as claimed in claim 1, further comprising:
a first upper pad formed on a front surface of the resin member, the first upper pad being configured to contact the upper side of the electrode;
a first lower pad formed on a rear surface of the resin member, the first lower pad being configured to contact to the bottom side of the electrode;
a second upper pad formed on the front surface of the resin member, the second upper pad being configured to contact to an upper side of the conductive material part; and
a second lower pad formed on the rear surface of the resin member, the second lower pad being configured to contact the bottom side of the conductive material part.

7. The electronic component built-in board as claimed in claim 6, further comprising:
a first external terminal configured to contact either the upper side of the electrode or a front surface of a first upper pad, or configured to contact the upper side of the electrode and the front surface of the first upper pad;
a second external terminal configured to contact either the upper side of the conductive material part or a front surface of a second upper pad, or configured to contact the upper side of the conductive material part and the front surface of the second upper pad;
a third external terminal configured to contact either the lower side of the electrode or a rear surface of a first lower pad, or configured to contact the lower side of the electrode and the rear surface of the first lower pad; and
a fourth external terminal configured to contact either the bottom side of the conductive material part or a rear surface of a second lower pad, or configured to contact the bottom side of the conductive material part and the rear surface of the second lower pad.

8. The electronic component built-in board as claimed in claim 7, wherein the first, second, third and fourth external terminals include Au bumps and solder configured to cover the Au bumps.

9. The electronic component built-in board as claimed in claim 1, wherein resin formed from a different material from a material of the resin member is provided around a peripheral region of the bottom side of the conductive material part.

10. The electronic component built-in board as claimed in claim 1, wherein another electronic component is mounted on the electronic component via resin formed from a different material from a material of the resin member.

11. A semiconductor device comprising:
the electronic component built-in board of claim 1;
a semiconductor chip; and
a wiring board including a chip connection pad connected to the semiconductor chip and a board connection pad connected to the electronic component built-in board,
wherein the chip connection pad is formed on a principle plane of the wiring board, and the board connection pad is formed on another plane of the wiring board being opposite to the principle plane of the wiring board.

12. A manufacturing method for manufacturing an electronic component built-in board configured to include an electronic component having and electrode, a conductive material part arranged in an identical plane to the electronic component, and a resin member, the manufacturing method comprising the steps of:
providing the electronic component and the conductive material part on a support member;
forming the resin member so as to cover at least a side of the electronic component and a side of the conductive material part;
exposing an upper side of the electrode and an upper side of the conductive material part from the resin member; and
removing the support member after the step of exposing.

13. The manufacturing method as claimed in claim 12, wherein in the step of removing, an ashing process is performed so as to remove parts of the resin member covering the upper side of the electrode and the upper side of the conductive material part.

14. The manufacturing method as claimed in claim 12, further comprising a step of forming upper pads:
wherein, in the step of forming upper pads, at least one of a first upper pad connected to the electrode and a second upper pad connected to an upper side of the conductive material part is formed on an upper surface of the resin member; and
in the step of forming lower pads, at least one of a first lower pad connected to a bottom side of the electrode and a second lower pad connected to a bottom side of the conductive material part is formed on a rear surface of the resin member.

15. The manufacturing method as claimed in claim 12, wherein the support member includes a main support part and an adhesion layer, and
in the step of removing the support member, only the main support part is removed.

16. The manufacturing method as claimed in claim 12, wherein the conductive material part is formed on the support member via resin formed from a different material from a material of the resin member.

17. The manufacturing method as claimed in claim 12, wherein another electronic component is mounted on the electronic component via resin formed from a different material from a material of the resin member.
